(19) United States
(12) Patent Application Publication
(10) Pub. No.: US 2013/0033929 A1
(43) Pub. Date: Feb. 7, 2013

(54) WRITE SCHEME IN A PHASE CHANGE MEMORY

(71) Applicant: Jin-Ki Kim, Ottawa (CA)

(72) Inventor: Jin-Ki Kim, Ottawa (CA)

(73) Assignee: MOSAID TECHNOLOGIES INCORPORATED, Ottawa, ON (CA)

(21) Appl. No.: 13/636,547

(22) PCT Filed: Apr. 26, 2011
(86) PCT No.: PCT/CA2011/000472

§ 371 Date: Sep. 21, 2012

Related U.S. Application Data
(60) Provisional application No. 61/327,979, filed on Apr. 26, 2010.

(51) Int. Cl. G11C 11/00

(52) U.S. Cl. 365/163; 365/148

(57) ABSTRACT

In a phase change memory, an input data corresponding to a plurality of memory cells is received and a previous data is read from the plurality of memory cells. The input data is compared with the previous data. In the case where the input data is different from the previous data for one or more of the plurality of memory cells and a write count is less than a maximum value, one or more of the plurality of memory cells is programmed with the input data and the write count is updated or incremented. Such operations of data comparison and update of the write count are repeated. If the write count reaches the maximum value, it will be determined that the writing is failed.

### CROSS-REFERENCE TO RELATED APPLICATIONS

This application claims priority from U.S. Provisional Patent Application Ser. No. 61/327,979 filed on Apr. 26, 2010 entitled “WRITE SCHEME IN PHASE CHANGE MEMORY,” the entirety of which is incorporated by reference herein.

### TECHNICAL FIELD

The present invention relates generally to memory devices. More specifically, the present invention relates to semiconductor memory devices with features, for example, iterative verification of written or programmed data.

### BACKGROUND

Examples of semiconductor memory devices are nonvolatile memory devices that are phase change memories (PCMs). PCMs use phase change materials, for example, such as chalcogenide, for storing data. A typical chalcogenide compound is Ge₂-Sb₂-Te₅ (GST). The phase change materials are capable of stably transitioning between crystalline and amorphous phases by controlling heating and cooling processes. The amorphous phase exhibits a relatively high resistance compared to the crystalline phase which exhibits a relatively low resistance. The amorphous state, also referred to as the “reset” state or logic “0” state, can be established by heating the GST compound above a melting temperature (e.g., 610° C.), then rapidly cooling the compound. The crystalline state, which is referred to as the “set” state or logic “1” state, can be established by heating the GST compound above a crystallizing temperature (e.g., 450° C.) for a longer period of time sufficient to transform the phase change material into the crystalline state. The crystallizing temperature is below the melting temperature of 610° C. The heating period is followed by a subsequent cooling period.

FIG. 1 depicts a typical phase change memory cell. Referring to FIG. 1, a phase change memory (PCM) cell 110 includes a storage element 112 and a switching element 114. The switching element 114 is used to selectively access the storage element 112 of the PCM cell 110. A typical example of the storage element 112 is a variable resistor formed by a phase change material (e.g., GST). The resistance of the variable resistor can be altered by transforming a structure (or a characteristic) between the crystalline and amorphous phases.

FIG. 2 shows a structure of an example storage element as the storage element 112 of PCM cell 110 shown in FIG. 1. Referring to FIG. 2, a heater 122 is located between a first electrode 124 and a chalcogenide compound 126 that is contacted by a second electrode 128, typically with low resistance. The first electrode 124 is used to make a low resistance contact to the heater 122. The heater 122 causes a portion of the chalcogenide compound 126 to transform from the crystalline state to the amorphous state in a physical space referred to as a programmable volume 130.

FIG. 3 shows the relationship of time and temperature for both reset and set programming of the storage element shown in FIG. 2 for the phase change memory. Referring to FIGS. 2 and 3, the phase change memory (PCM) cell can be programmed (or written) to two states (or phases): (i) the amorphous or “reset” state; and (ii) the crystalline or “set” state. Such programming of the states can be achieved by heating the phase change layer (the chalcogenide compound 126 of the storage element) by the heater 122. To program the reset state, the phase change layer is heated to a temperature T_Reset with a current I_Reset through the heater 122 for a duration of tP_Reset, then quickly cooling down the phase change layer. To program the set state, the phase change layer is heated to a temperature T_Set with a current I_Set through the heater 122 and to maintain the phase change layer at temperature T_Set for a duration of tP_Set and then cooling down the phase change layer. The time interval tP_Set of the current I_Set exceeds tP_Reset of the current I_Reset. Pulses of the applied currents I_Reset and I_Set are referenced at “132” and “134”, respectively.

FIGS. 4A and 4B show a phase change memory (PCM) in a programmed set state “SET” and a programmed reset state “RESET”, respectively. The phase change materials (or the phase change layers) are thermally activated. Referring to FIGS. 2, 3, 4A and 4B, the PCM cell is programmed to the set state by applying the current I_Set for the duration of tP_Set. The amount of heat applied to the phase change layer is proportional to I²×R, where “I” is a currency value of I_Set through the heater 122 and “R” is a resistance of the heater 122. While the PCM cell is being programmed to the set state (“SET”) as shown in FIG. 4A, the phase change layer is changed to the crystalline state, resulting in a lower cell resistance compared to the reset state (“RESET”) as shown in FIG. 4B. Similarly, the phase change memory cell is programmed to the reset state by applying the current I_Reset for the duration of tP_Reset. While the PCM cell is being programmed to the reset state, a certain volume of phase change layer is changed to the amorphous state (of FIG. 4B), resulting in a higher cell resistance than the set state (of FIG. 4A). The programmable volume in the phase change layer is generally a function of the amount of heat applied to the phase change layer.

Phase change memory devices typically use the amorphous state to represent a logical “0” state (or RESET state) and the crystalline state to represent a logical “1” state (or SET state). Table 1 summarizes typical properties of an example phase change memory.

TABLE 1
Phase Change Memory Properties

| Data | “0” | “1” |
|---|---|---|
| Program State | Reset | Set |
| Resistance | High (>100 KΩ) | Low (10 KΩ) |
| Read Current | Low | High |
| Material Phase | Amorphous | Crystalline |
| Write Pulse | Approximately 50 ns | Approximately 200 ns |
| | (tP_Reset) | (tP_Set) |

FIG. 5 illustrates the distribution of PCM cell resistance Rpm for the SET state 136 and the RESET state 138. Specifically, the SET state has a resistance distribution spanning from values RS1 and RS2 (e.g., approximately 10 KΩ). The RESET state has a resistance distribution spanning from two higher values RR1 (e.g., approximately 100 KΩ) and RR2. The resistance values RS2 and RR1 are determined for a desired yield. For example, if the desired yield is 99%, then 1% of the programmed PCM cells could have a SET resistance higher than RS2 or a RESET resistance lower than RR1 and be deemed to have failed.

In recent years, various phase change memory (PCM) cells have been used. FIG. 6 shows a diode based PCM cell that includes a diode 144 connected to a storage element 142. The cathode of the diode 144 is connected to a wordline 148. The storage element 142 is connected to a bitline 146. The diode 144 is a two-terminal device. Tree-terminal devices can also be used as the switching elements. FIG. 7 shows a field effect transistor (FET) (or MOS transistor) based PCM cell that includes a FET (MOS transistor) 154 and a storage element 152. The gate, drain and source of the transistor 154 are connected to a wordline 158, the storage element 152 and the ground, respectively. The storage element 152 is connected to a bitline 156. FIG. 8 shows a bipolar transistor based PCM cell that includes a bipolar transistor (of PNP type) 164 and a storage element 162. The base, emitter and collector of the bipolar transistor 164 are connected to a wordline 168, the storage element 162 and the ground, respectively. The storage element 162 is connected to a bitline 166.

A memory cell array can be formed by a plurality of PCM cells shown in FIG. 6, which are connected to a plurality of bitlines 146 and wordlines 148. Similarly, a memory cell array can be formed by a plurality of PCM cells shown in FIG. 7, which are connected to a plurality of bitlines 156 and wordlines 158. A memory cell array can be formed by a plurality of PCM cell arrays shown in FIG. 8, which are connected to a plurality of bitlines 166 and wordlines 168.

Each of the storage elements 142, 152, and 162 is formed by a variable resistor that functions as the storage element 112 as shown in FIG. 1. Each of the diode 144, FET 154, and bipolar transistor 164 functions as the switching element 114 shown in FIG. 1 and functions as an access element to the storage element connected thereto.

To use the diode 144 shown in FIG. 6 or the bipolar transistor 164 shown in FIG. 8, as the switching element 114 in the memory cell, is an attempt to reduce cell size, so as to improve memory density. Further improvements in memory system density are needed to continue to reduce memory system cost and increase memory capacity driven in part by increased data traffic in electronic systems.

### SUMMARY

According to one aspect of the present invention, there is provided a method for writing data into a phase change memory having a plurality of memory cells. The method comprises: receiving input data comprising a plurality of bits; reading previous data comprising a plurality of bits read from the plurality of memory cells; comparing the input data with the previous data in parallel with the reading; determining whether one or more of bits are different between the input data and the previous data to provide a data determination result; and programming the one or more of the plurality of memory cells with the input data in response to the data determination result.

The method may further comprise determining whether a count value is less than a maximum value to provide a count determination result. Advantageously, the programming is performed and the count value is updated in response to the data determination result and count determination result.

The receiving input data may further comprise receiving a burst of the input data, the burst including a plurality of data.

In another aspect, the present invention features an apparatus for writing a phase change memory comprising a sense amplifier including a bias transistor and a differential voltage amplifier.

For example, the bias transistor is in communication with a positive input of a differential voltage amplifier. One of a plurality of memory cell is in communication with the positive input of the differential voltage amplifier. A sense voltage at the positive input of the differential voltage amplifier is in proportion to a bias resistance of the bias transistor and a memory cell resistance of the one of the plurality of memory cells. A reference voltage is in communication with a negative input of the differential voltage amplifier. The reference voltage is between the sense voltage obtained at the positive input of the differential voltage amplifier for the one of the plurality of memory cells in a SET state and the one of the plurality of memory cells in a RESET state.

The apparatus may further comprise a register configured to retain the state of a plurality of bits in data. A write driver has a write current branch, a reset current branch and a set current branch. The reset current branch is enabled by a RESET state and disabled by the data-mask state. The set current branch is enabled by a SET state and disabled by the data-mask state. The write current branch mirrors a current of one of the reset current branch and the set current branch.

The apparatus may further comprise an equivalence circuit configured to set the data-mask state corresponding to a bit in the data having the SET state when a corresponding sensed bit in the plurality of memory cells has the SET state, and to set the data-mask state corresponding to a bit in the data having the RESET state when a corresponding sensed bit in the plurality of memory cells has the RESET state.

In another aspect, the present invention features a phase change memory system comprising a memory array including a plurality of memory cells. For example, each of the plurality of memory cells is located at one of a plurality of rows and at one of a plurality of columns.

The phase change memory may include a plurality of local column selectors, a global column selector, a sense amplifier. Each of the plurality of local column selectors is in communication with a plurality of columns. The global column selector is in communication with the plurality of local column selectors. The sense amplifier is in communication with the global column selector.

In an example, the sense amplifier includes a bias transistor and a differential voltage amplifier. The bias transistor is in communication with a positive input of a differential voltage amplifier. One of a plurality of memory cell is in communication with the positive input of the differential voltage amplifier.

For example, a sense voltage at the positive input of the differential voltage amplifier may be in proportion to a bias resistance of the bias transistor and a memory cell resistance of the one of the plurality of memory cells. A reference voltage is in communication with a negative input of the differential voltage amplifier. The reference voltage is between the sense voltage obtained at the positive input of the differential voltage amplifier for the one of the plurality of memory cells in a SET state and the one of the plurality of memory cells in a RESET state.

In an example, a register retains the state of a plurality of bits in data. A write driver is in communication with the global column selector. A write driver may have a write current branch, a reset current branch and a set current branch. The reset current branch is enabled by a RESET state and disabled by the data-mask state. The set current branch is enabled by a SET state and disabled by the data-mask state. The write current branch mirrors a current of one of the reset current branch and the set current branch.

In an example, an equivalence circuit sets the data-mask state corresponding to a bit in the data having the SET state when a corresponding sensed bit in the plurality of memory cells has the SET state, and sets the data-mask state corresponding to a bit in the data having the RESET state when a corresponding sensed bit in the plurality of memory cells has the RESET state.

In accordance with another aspect of the present invention, there is provided a phase change memory (PCM) comprising: an array having a plurality of memory cells with k rows×j columns, each of k and j being an integer greater than one; a column selector configured to select at least one of the j columns; a row selector configured to select at least one of the k rows; a data writer configured to provide input data to selected one or ones of the plurality of memory cells through the selected one or ones of the columns and rows; an input data retainer configured to retain the input data; and a data write controller configured to control the data writer. The data writer comprises: a first current circuit configured to perform a first current flow when a first state of the input data, a second current circuit configured to perform a second current flow when a second state of the input data, and a third current circuit configured to perform a third current flow, the third current being proportional to the first current and the second current in the first and second states of the input data. Operations of the first and second current circuits being controlled by the data write controller.

In accordance with another aspect of the present invention, there is provided a memory system comprising a plurality of memory banks, each bank comprising a plurality of phase change memory (PCM) cell arrays, each array comprising PCM defined above.

In an example of a phase change memory, an input data corresponding to a plurality of memory cells is received. Also, a previous data is read from the plurality of memory cells and the input data is compared with the previous data. If the input data is different from the previous data for one or more of the plurality of memory cells and a write count is less than a maximum value, one or more of the plurality of memory cells will be programmed with the input data and the write count is incremented. Such operations of data comparison and update of the write count are repeated. If the write count reaches the maximum value, it will be determined that the writing is failed.

Other aspects and features of the present invention will become apparent to those ordinarily skilled in the art upon review of the following description of specific embodiments of the invention in conjunction with the accompanying figures.

### BRIEF DESCRIPTION OF THE DRAWINGS

Embodiments of the present invention will now be described, by way of example only, with reference to the attached Figures, wherein:

FIG. 1 is a schematic diagram illustrating a phase change memory (PCM) cell;

FIG. 2 is a cross-sectional view showing a structure of a PCM cell;

FIG. 3 is a graph of temperature change during set and reset operations of a PCM cell;

FIGS. 4A and 4B are cross-sectional views of the PCM in the set state and the reset state, respectively;

FIG. 5 is a graph of the resistance distribution for the set and the reset states.

FIG. 6 is a schematic diagram illustrating a diode based PCM cell;

FIG. 7 is a schematic diagram illustrating a field effect transistor (FET) based PCM cell;

FIG. 8 is a schematic diagram illustrating a bipolar transistor based PCM cell;

FIG. 9 is a schematic diagram illustrating a memory device to which embodiments of the present invention are applicable;

FIG. 10 is a cross-sectional view of a memory device including a plurality of diode based PCM cells according to an embodiment of the present invention;

FIG. 11 is a timing diagram showing a single data rate (SDR) burst write operation;

FIG. 12 is a timing diagram showing an SDR burst read operation;

FIG. 13 is a graph of the resistance distribution for the set and the reset states in relation to reference resistances for the write and the read operations;

FIG. 14 is a flow chart of an example of the write operation;

FIG. 15 is a schematic diagram illustrating PCM cell arrays included in the memory device according to an embodiment of the present invention;

FIG. 16 is a schematic diagram illustrating the PCM cell array shown in FIG. 15 with write operation;

FIG. 17 is a schematic diagram illustrating the PCM cell array shown in FIG. 15 with read operation;

FIG. 18 is a block diagram illustrating a phase change memory bank architecture in accordance with an embodiment of the present invention;

FIG. 19 is a block diagram illustrating a phase change memory architecture in accordance with an embodiment of the present invention;

FIG. 20 is a schematic diagram illustrating a local column selector shown in FIG. 18;

FIG. 21A is a schematic diagram illustrating a global column selector shown in FIG. 18;

FIGS. 21B, 21C, 21D and 21E are schematic diagrams illustrating examples of a global column decoder shown in FIG. 21A;

FIG. 22 is a schematic diagram illustrating a write driver portion or circuit of a write driver and sense amplifier shown in FIG. 18;

FIG. 23A is a schematic diagram illustrating a sense amplifier portion or circuit of a write driver and sense amplifier shown in FIG. 18;

FIG. 23B is a schematic diagram illustrating an example of a read data retainer applicable to the sense amplifier shown in FIG. 21A;

FIG. 24 is a schematic diagram illustrating a row decoder shown in FIG. 18;

FIG. 25A is a timing diagram illustrating a write operation of the memory according to an embodiment of the present invention;

FIG. 25B is a timing diagram illustrating a read operation of the memory according to an embodiment of the present invention;

FIG. 26 is a timing diagram illustrating an example verification of a write operation;

FIG. 27 is a timing diagram illustrating an example write operation showing SDR burst timing;

FIG. 28 is a timing diagram illustrating an example verification of a write operation according to an embodiment of the present invention;

FIG. 29 is a timing diagram illustrating the write operation showing SDR burst timing according to an embodiment of the present invention;

FIG. 30 is a schematic diagram illustrating an equivalence function performed in a write driver and sense amplifier according to an embodiment of the present invention;

FIG. 31 is a schematic diagram illustrating an equivalence function performed in a register according to an embodiment of the present invention;

FIG. 32A is a schematic diagram illustrating an example of verification performed as shown in FIG. 31 register 530 shown in Figures shown in FIG. 18;

FIG. 32B is a schematic diagram illustrating an example of the 16-bit comparators shown in FIG. 32A; and

FIGS. 33A and 33B are schematic diagrams illustrating PCM cell arrays applicable to memory devices according to embodiments of the present invention.

### DETAILED DESCRIPTION

Generally, embodiments of the present invention relate to semiconductor memory device. Embodiments of the present invention relate to phase change memory (PCM) devices and systems.

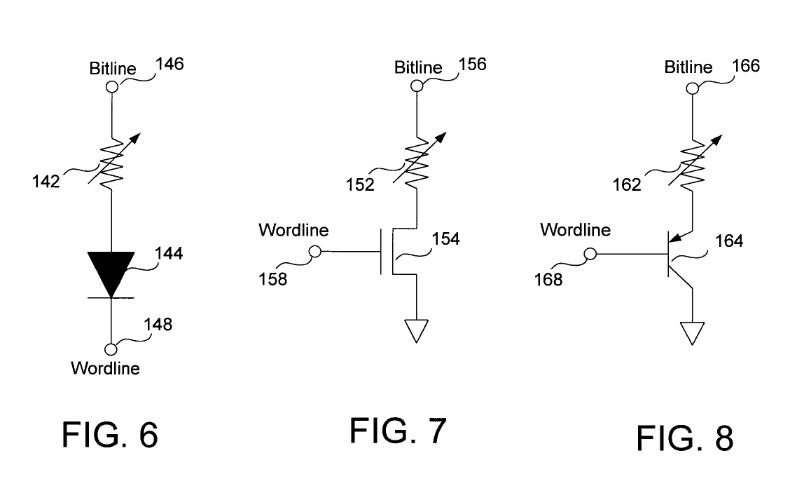

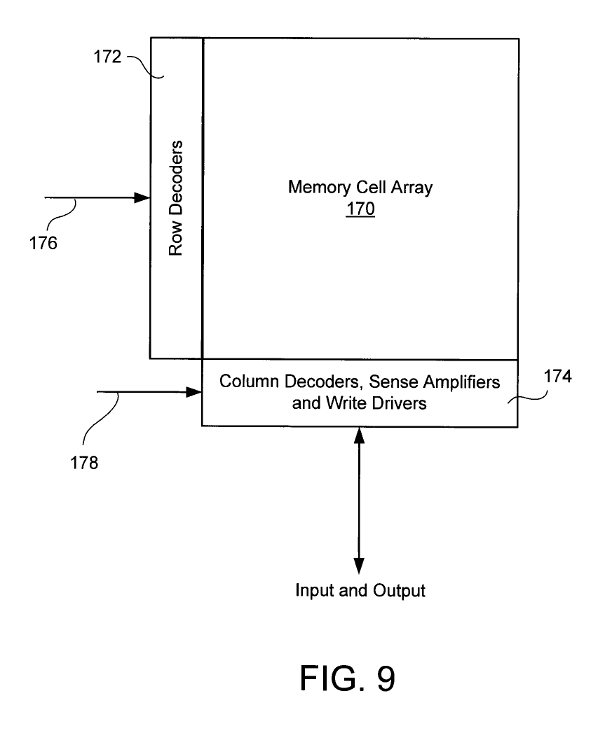

The memory cell distribution shown in FIG. 5 can be improved by decreasing the highest SET resistance RS2, increasing the lowest RESET resistance RR1, or both. This separates the two states further, which improves sensing margin. Improved sensing margin advantageously improves sensing reliability in the presence of noise as well as sensing speed. The resistance distributions of the SET and RESET states can be improved by reading a previously written memory cell and verifying that the state of the read cell matches what was previously written. This is referred to as a “write verify” or a “verification read” operation. If the read cell fails the write verify operation, the cell can be written again in an attempt to “correct” the memory bit. In one example, a bit fails because the amorphous region (the programmable volume) 130 in FIG. 4B is insufficiently formed or insufficiently removed through crystallization. The step of writing a memory cell is repeated for a fixed number of iterations, beyond which the memory is considered a permanent failed bit. In one example, a limit is set on the number of attempted write operations to screen out bits that have other latent failure mechanisms that could affect future reliability.

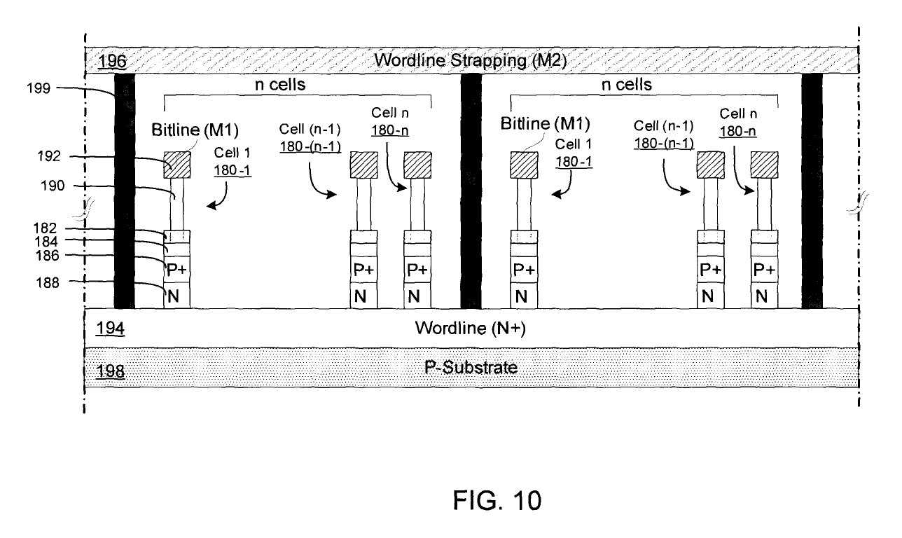

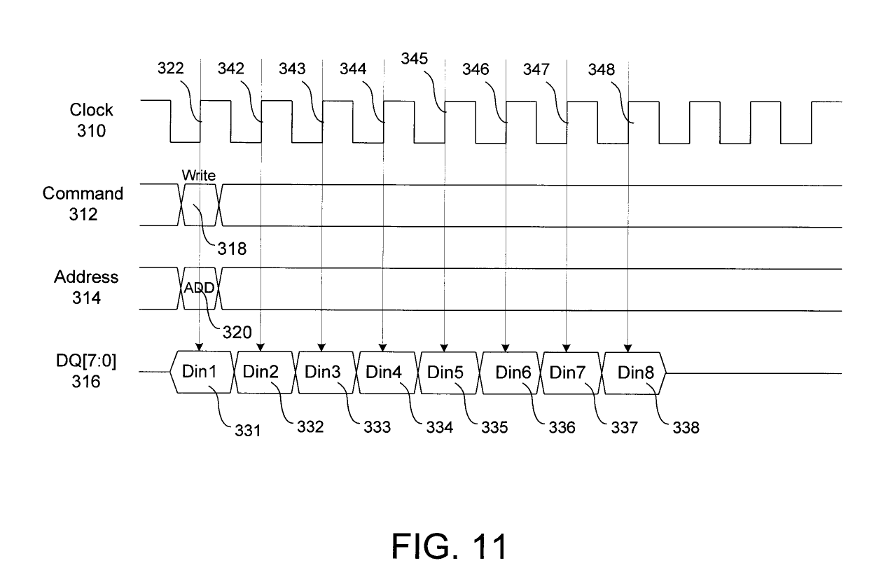

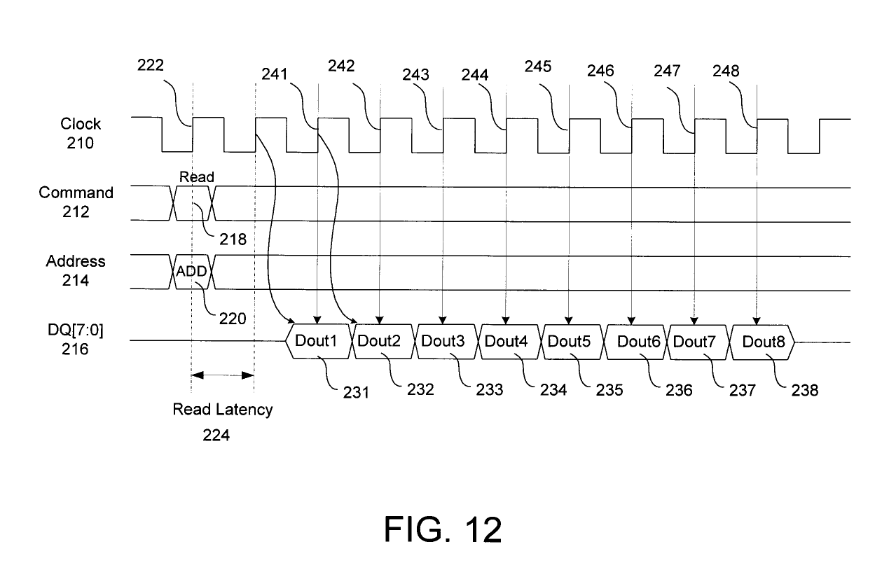

In one embodiment of the present invention, the write verify operation is performed during write data input. This advantageously improves write performance and tightly controls (e.g., reduces) the cell resistance distribution thereby reducing power consumption. For example, power consumption is reduced when sensing speed is increased, because bias transistors can be shut off sooner. One embodiment of the present invention is a diode based PCM device with a memory cell as shown in FIG. 6, however other embodiments use either a field effect transistor (FET) based PCM memory cell as shown in FIG. 7 or a bipolar-based PCM memory cell as shown in FIG. 8.

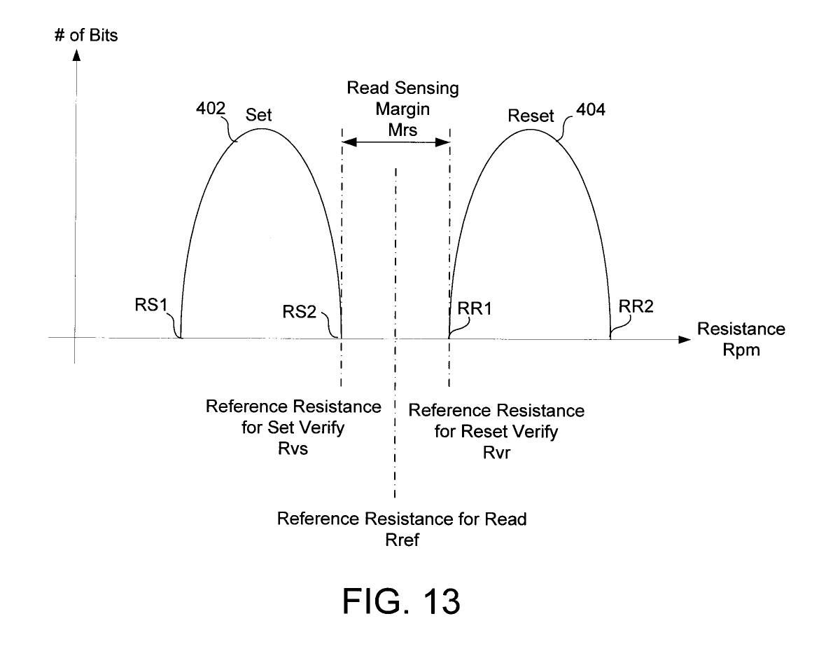

FIG. 9 shows a memory device to which embodiments of the present invention are applicable. Referring to FIG. 9, a memory device includes a memory cell array 170 with peripheral circuitry including row decoders 172 and column decoders, sense amplifiers and write drivers 174. The row decoders 172 receive signals 176 including pre-decoded address information and control information. The column decoders, sense amplifiers and write drivers 174 receive signals 178 including control information. Also, the column decoders, sense amplifiers and write drivers 174 communicate with input and output (I/O) circuits (not shown) for data write and read. The control information for the rows (wordlines) and columns (bitlines) is provided by memory device control circuitry (not shown).

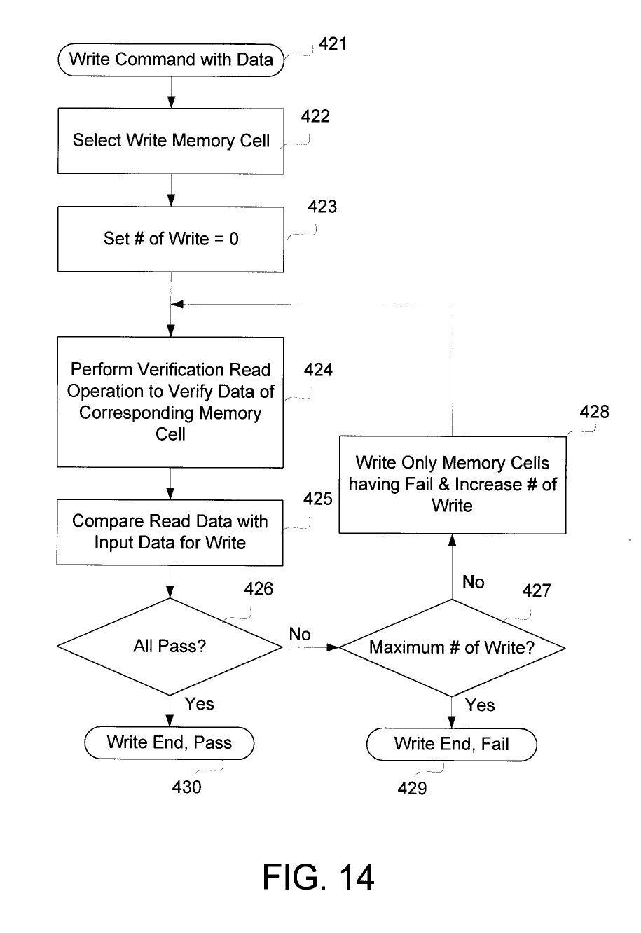

FIG. 10 shows a memory device including a plurality of diode based phase change memory (PCM) cells according to an embodiment of the present invention. Referring to FIG. 10, the device has a plurality of groups of cell arrays, each group comprising cell 1, cell (n−1), cell n. In the particular example, n memory cells 180-1, . . . , 180-(n−1) and 180-n are repeated to form one layer of cell arrays, n being an integer greater than one. For example, n is 64, but it is not limited. Each of the n memory cells 180-1, . . . , 180-(n−1) and 180-n is configured with GST (chalcogenide compound) 182, a self-aligned bottom electrode 184 and a vertical P-N diode connected in series as an anode 186 and a cathode 188. A heater 190 is between the GST 182 and a bitline 192 with a top electrode (not shown), which is configured with low resistance.

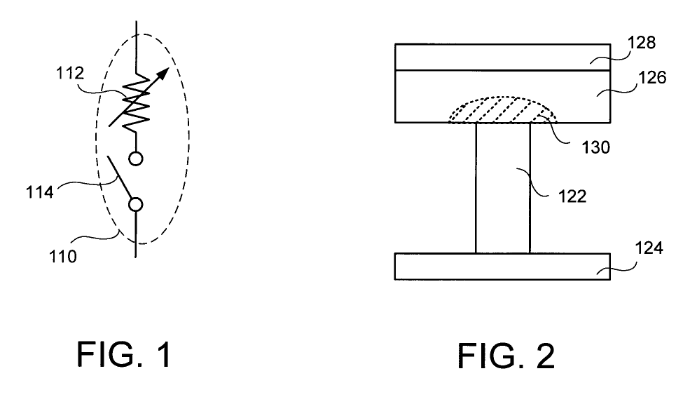

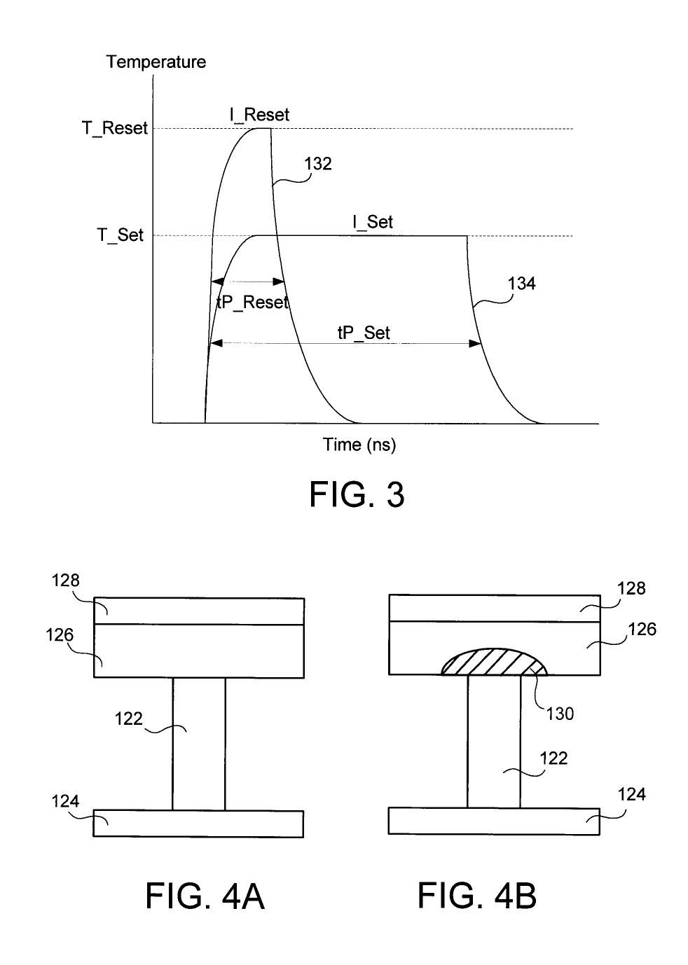

The heater 190 corresponds to the heater 122 of FIGS. 2 and 4A, 4B. The GST 182 corresponds to the chalcogenide compound 126 of FIGS. 2 and 4A, 4B. The top electrode, which is the contact of the heater 190 and the bitline 192, and the bottom electrode 184 correspond to the first electrode 124 and the second electrode 128 of FIGS. 2 and 4A, 4B, respectively. The chalcogenide compound develops the programmable volume 130 as shown in FIGS. 2 and 4B. The diode having the anode 186 and cathode 188 corresponds to the diode 144 shown in FIG. 5 and functions as the switching element 114 of FIG. 1.

The bitline 192 formed by a first metal layer (M1). The cathode 188 of the diode is connected to a wordline 194 formed in an N+ doped base of a P substrate 198. In the particular example, the substrate 198 is formed by a semiconductor layer with a P-type dopant. A wordline strap 196 uses a second metal layer (M2) to reduce the word line resistance. A wordline strap can be used for every n phase change memory (PCM) cells. The choice of how often to connect (e.g., “strap”) the word line 194 with the low resistance strap 196 is made by strapping enough to lower the wordline resistance between a wordline driver (described later) and the memory cell that is the furthest from the strap connection. The strapping is not, however, made to significantly increase the overall memory array size. The wordline 194 and the strap 196 are connected by a contact 199. The bitline 192 and the wordline 194 correspond to the bitliine 146 and the wordline 148, respectively, shown in FIG. 6. In the cases where the FET and bipolar based PCM cells are implemented, the bitline 192 corresponds to each of the bitliines 156 and 166 and the wordline 194 corresponds to each of the wordlines 158 and 168 shown in FIGS. 7 and 8.

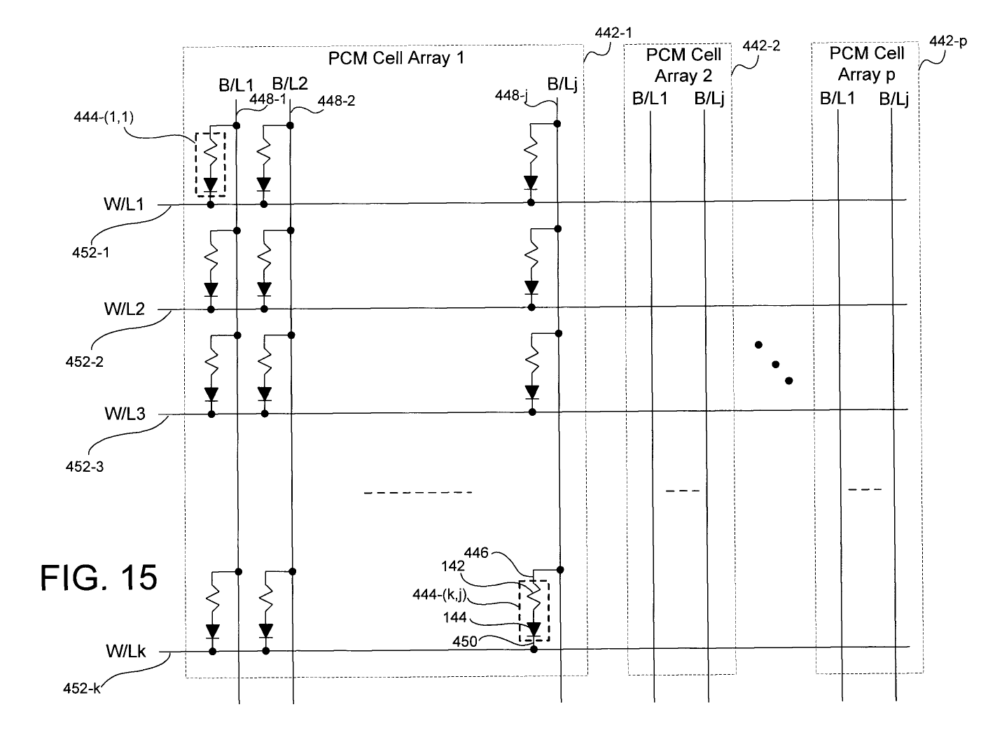

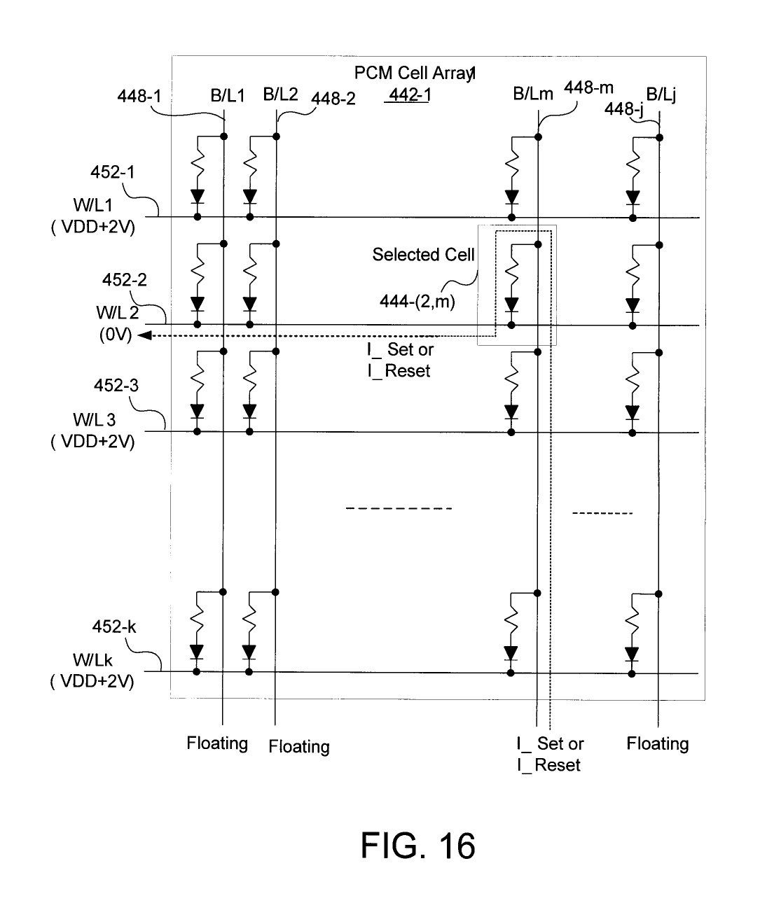

To improve READ and WRITE performance, a burst read with prefetch and a burst write with buffered data can be used as shown in FIGS. 11 and 12.

Referring to FIG. 11 that shows an SDR burst WRITE operation, a burst write operation latches a command 312 (e.g., “WRITE” command 318) and an address 314 (e.g., “ADD” 320) at an edge 322 of a clock signal 310. A series of data (DQ[7:0]) 316, specifically 331 through 338 (“Din1” to “Din8”) is written on successive edges 342 through 348 of the clock signal 310. The series of data are prefetched with the first data 331 (Din1) available concurrent with the ADD 320 and WRITE command 318. The data 316 (Din1 to Din8) are written from sequential memory addresses starting with the base address ADD 320. The data is transferred to the memory at clock edges, with one clock edge used for each data. In this example, the structure of each data Din1-Din8 is a byte (or eight bits). Data can be of a single byte or multiple bytes.

In PCM devices, the memory cell resistances for both set and reset states are tightly controlled to minimize bit error rate (BER), improve memory cell reliability, improve sensing speed, reduce sensing power and extend device lifetime. BER refers to the rate at which memory cells fail to provide the correct state after being programmed. A memory cell that is marginally programmed can still fail occasionally due to random noise, from power supply bounce for example. Memory cell reliability refers to the ability for a memory cell to perform as well “in the field” or the customer site as it does when tested by the manufacturer. Sensing speed is improved by increasing the signal available to the sense amplifier. Sensing power is reduced in one example, by shortening the duration that current sources must be on. Device lifetime refers to the time that a device will continue to properly function despite the effects of aging. An example of device aging is a shifting of a transistor threshold due to migration of dopants used to adjust the threshold.

Referring to FIG. 12 that shows a single data rate (SDR) burst READ operation, the burst operations as shown use a single data rate (SDR) timing where one edge of a clock signal 210 is used to latch data. Additional performance is obtained by using a double data rate (DDR) where both edges of the clock signal 210 are used to latch data.

The clock signal 210 is used to latch a command 212, (e.g., READ command 218) and an address 214, (e.g., “ADD” 220) with an edge 222 of the clock signal 210. The address ADD 220 defines the starting location for reading the series of data DQ[7:0] 216, with each data read to a sequential memory address. Latency 224 is added to allow time to buffer the data to be read, for example latching the data in a register. The data is then read to the memory with a series of data 216, specifically 231 through 238 (e.g., eight data “Dout1” to “Dout8”), transferred to the memory at clock edges 241 through 248, with one clock edge used for each data. In this example, the structure of each data Dout1-Dout8 is a byte (or eight bits). Data can be of a single byte or multiple bytes.

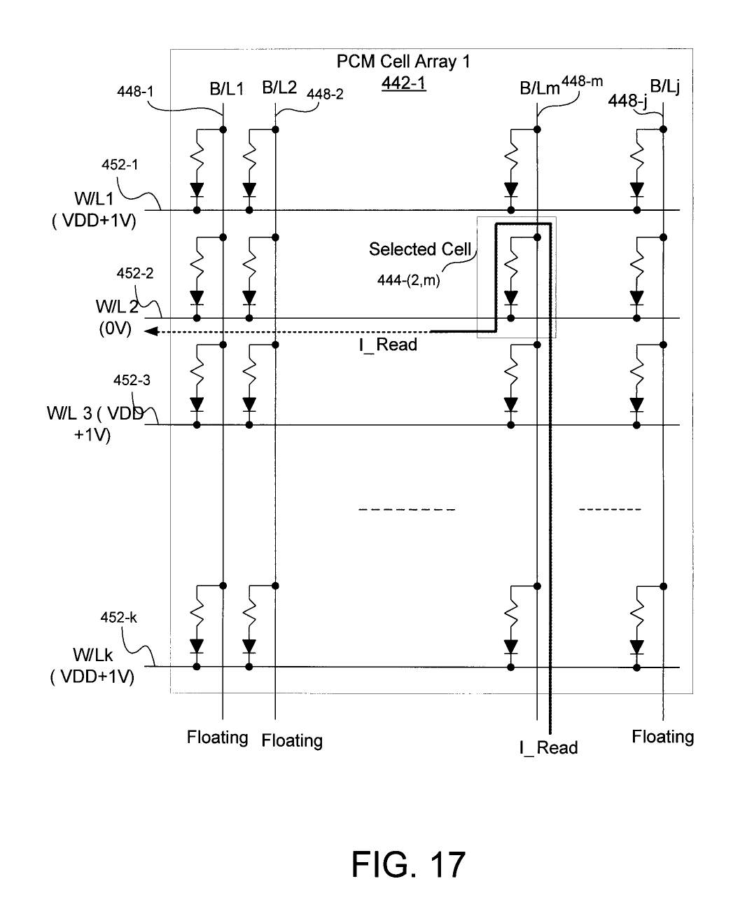

FIG. 13 shows the resistance distribution for the set and the reset states in relation to reference resistances for the write and the read operations. Referring to FIG. 13, a set state 402 has a range of resistance values RS1 (a reference resistance for set verify) to RS2 (a reference resistance for reset verify). A reset state 404 has a range of resistance values RR1 to RR2. The separation of the two resistance ranges defines a read sensing margin Mrs. During a read operation, the sense amplifier uses a reference resistance for reading Rref that can be set anywhere within the read sensing margin Mrs. In one example, the reference resistance for read Rref is centered between the highest SET state resistance RS2 and the lowest RESET state resistance RR1. During a write verify operation, a reference resistance for set verify Rvs (e.g., RS2) is used to verify that the set state was properly programmed in the memory cell. Similarly, a reference resistance for reset verify Rvr (e.g., RR1) is used to verify that the reset state was properly programmed in the memory cell.

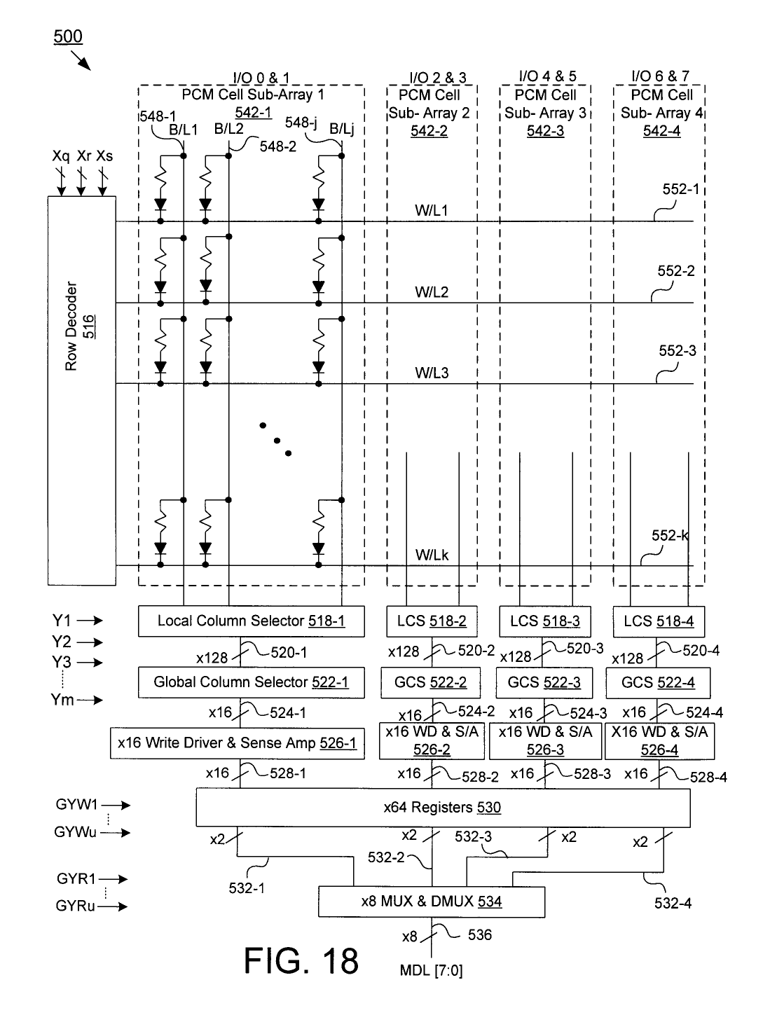

FIG. 14 depicts a flow chart of an example of the write operation. A write command with data is interpreted by the PCM device and performed at step 421, and as further described in FIG. 11. At step 422, the memory cell corresponding to the memory address is selected with row and column selectors (or decoders) and the data 231-238 (Din1 to Din8 shown in FIG. 11) is buffered in a register for the write drivers. At step 423 a write counter (not shown) is initialized to a zero value to indicate that zero writes have been performed. The value of the write counter is updatable or changeable. At step 424, a write verify operation is performed for the selected memory cells comprising sensing the stored data with a sense amplifier. At step 425, the read data and the input data are compared. At step 426, if the comparison of step 425 passes (a positive determination), then the write operation ends at step 430, otherwise the total number of write operations is assessed at step 427. If the total number of write operations (e.g., the current value) reaches a predetermined value; for example, the number is equal to the maximum permissible number of write operations (e.g., a maximum value) (a positive determination at step 427), then proceed to step 429 to indicate a write failure. In one example, a write failure sets a fail flag. If the number of write operations is less than the maximum permissible number of write operations then proceed to step 428. At step 428, only the memory cells bits in the data that failed are rewritten, the write counter is updated or incremented and proceeds to step 424. The subsequent operations are performed.

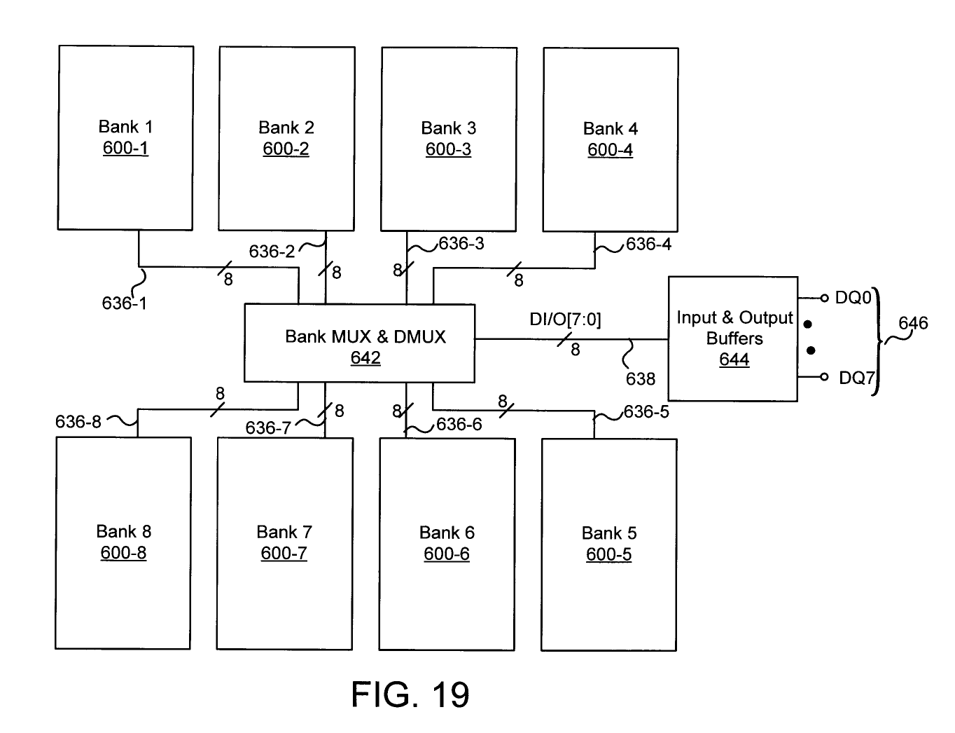

FIG. 15 shows phase change memory (PCM) cell arrays included in a memory device according to an embodiment of the present invention.

Referring to FIG. 15, a memory device includes a plurality of (p) cell arrays (PCM cell array 1, PCM cell array 2, . . . , PCM cell array p), p being an integer greater than one. For example, p is 4 or 8. Circuit structure of the PCM cell arrays is identical to each other. Each group of the p PCM cell arrays 442-1-442-p includes a plurality of (j) bitlines (B/L1-B/Lj). A plurality of (k) wordlines “W/L1”-“W/Lk” 452-1-452-k is connected to PCM cells of the PCM cell arrays 442-1-442-p. Each of the PCM cell arrays includes a plurality of memory cells (k x j cells), k and m representing row and column numbers, respectively, each of k and j being an integer greater than one. For example, k is 512 and j is 256. Each of the memory cells includes a diode connected to a storage element, such as, for example, a diode based PCM cell including the diode 144 connected to the storage element 142 as shown in FIG. 6. A person skilled in the art would understand that p, k and j are not limited.

In FIG. 15, each of the storage elements is represented by a resistor (which is actually the variable resistor 142 as shown in FIG. 6). In general, a memory cell connected to a wordline and a bitline is represented by “444-(K,M)”, K representing the variable number of row, J representing the variable number of column in one of the p groups, 1≦K≦k, 1≦J≦m. In FIG. 15, memory cells 444-(1,1) and 444-(k,j) are shown. Each memory cell is coupled to a bitline and a wordline at a cross point thereof. Each of the memory cells has a first terminal 446 and a second terminal 450. The first terminal 446 corresponds to the first electrode 124 shown in FIGS. 2, 4A, 4B and the connection of the bitline 192 and the heater 190 shown in FIG. 10. FIG. 15 does not, however, show a heater connected to the variable resistor of a memory cell. The second terminal 450 corresponds to a junction of the cathode 188 and the wordline 194 as shown in FIG. 10. The first and second terminals 446 and 450 of the memory cell 444-(k,j) shown in FIG. 15 are connected to corresponding bitline “B/Lj” 448-j and wordline “W/Lk” 452-k, respectively. The bitlines are also referred to as “columns” and the wordlines are referred to as “rows.” The number of the columns in one cell array, j, is not limited and j may be equal to n that represents the number of PCM cells in a row as shown in FIG. 10.

For example, when the bitline “B/Lj” 448-j and wordline “W/Lk” 452-k are appropriately biased, the switching element 144 of the memory cell 444-(k,j) is to conduct wordline. Data is stored in the PCM cell arrays by selecting a wordline corresponding to the location of all of the data and driving changes onto the bitlines that correspond to the various bits of the data. Data is retrieved from the PCM cell arrays by selecting a wordline corresponding to the location of all of the data and sensing changes onto the bitlines that correspond to the various bits of the data. Data can be stored in adjacent memory cells, which share a common wordline, in one example. In other examples, the data is stored in memory cells that are not physically adjacent to provide “sparcity.” Sparcity reduces the peak current requirements of power supply busses that supply power to sensing and driving circuits. In another example, the data is comprised of memory cells that are in one or more PCM cell arrays, either on the same PCM structure or on different PCM structures.

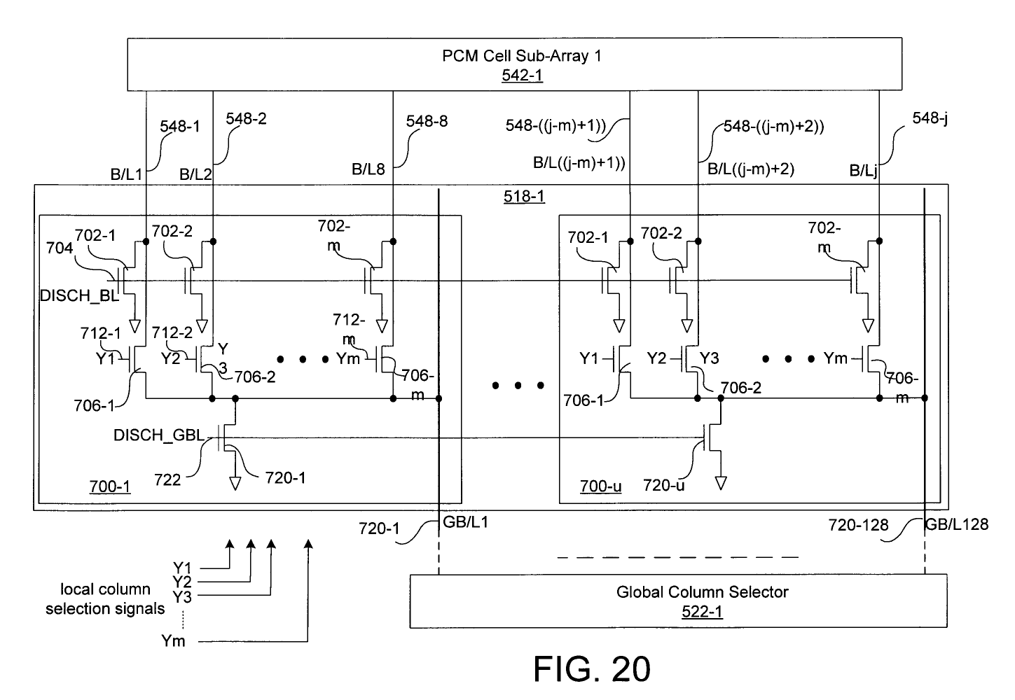

FIG. 16 shows one of the PCM cell arrays (e.g., PCM cell array 1, 442-1) shown in FIG. 15 for the purpose of describing a write operation “WRITE”. The selection of wordline and bitline is performed in accordance with the row and column addresses. In the particular example shown in FIG. 16, wordline “W/L2” 452-2 and bitline “B/Lm” 448-m are selected.

Referring to FIG. 16, wordline “W/L2” 452-2 is selected by changing its bias to 0V, while each of wordlines 452-1 and 452-3-452-k remains unselected with a bias of VDD+2 volts. In the particular example shown in FIG. 16, the voltage of VDD is 1.8 volts and the technology uses a 0.18 μm minimum feature size. However, a person skilled in the art would understand that other voltages, process technologies and cell characteristics are possible. Write current with a value of “I_Reset” or “I_Set” from a write driver (described later) flows through a selected bitline “B/Lm” 448-m and the selected wordline “W/L2” 452-2 via the selected cell 444-(2,m). The other bitlines are unselected and are left in a high impedance “floating” state, with the bitline potential held up by the parasitic capacitance of the bitline. Unselected cells connected to the unselected wordlines or floating bitlines are reverse biased and thus, no current flows through the unselected cells. The selected cell 444-(2,m) is used for writing data “1” by set current I_Set, or “0” by reset current I_Reset.

Unselected cells connected to either an unselected wordline or a floating bitline are reverse biased because the cathode of the diode switching element in each unselected memory cell is biased to a higher potential than the respective anode of the diode switching element, and thus no current flows through these unselected cells. More specifically, the diode switching elements in each unselected memory cell are reverse biased by 2V in the embodiment shown in FIG. 16. Although each diode will cease to conduct substantial current when the anode potential is at or below one diode threshold (typically 0.7V) of its cathode potential, the prevention of subthreshold current conduction requires a greater amount of reverse bias (e.g., 2V in this example). The requirement to suppress subthreshold leakage of the unselected memory cells during a WRITE operation helps reduce spurious weak programming of unselected memory cells, thereby reducing the “signal margin” or the sensing voltage (or current) difference between the two programmed states. The issue of maintaining a wide sense margin is even more critical when the PCM memory cells are programmed to four different levels in a further adaptation to the embodiment shown in FIG. 16. Each of the other PCM cell arrays 442-2-442-p in FIG. 15 are biased for a WRITE operation in a similar manner to that described for PCM cell array 442-1. A similar requirement to adequately reverse bias the unselected memory cells occurs with either the FET based or bipolar based switching element shown in FIGS. 7 and 8, respectively. In the case of a FET based switching element, the gate to source potential must be well below the FET threshold including any body effects. In the case of the bipolar based switching element, the base-emitter diode must be adequately reverse biased to prevent conduction.

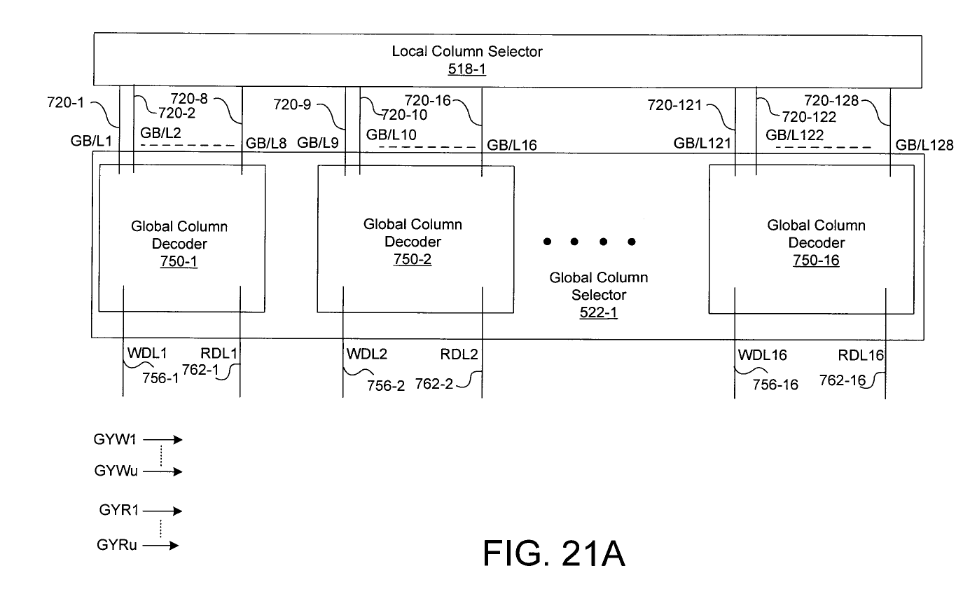

FIG. 17 shows the PCM cell array 442-1 of FIG. 15 biased for a READ operation. Referring to FIG. 17, wordline 452-2 is selected by changing its bias to 0V, while the unselected wordlines 452-1 and 452-3 through 452-k remain unselected with a bias of VDD+1 volt. For example, VDD is 1.8V and the technology uses a 0.18 μm minimum feature size. It should be understood that other voltages, process technologies and cell characteristics are comprehended in other embodiments. Read current “I_Read” from a sense amplifier (described later) flows to the selected wordline 452-2 through the selected cell 444-(2,m) and the selected bitline 448-m, while the other bitlines are left in a high impedance “floating” state, with the bitline potential held up by the parasitic capacitance of the bitline. Unselected cells connected to either an unselected wordline or a floating bitline are reverse biased and thus no current flows through the unselected cells.

Each of the other PCM cell arrays 442-2-442-p in FIG. 15 is biased for a READ operation in a similar manner to that described for PCM cell array 442-1. Similar to the WRITE case, unselected memory cells have their respective diode switching elements reverse biased beyond the level where substantial current flows and to a level required to suppress subthreshold leakage through each diode. The requirement to suppress subthreshold leakage of each of the unselected memory cells is further compounded by the cumulative effect of unselected memory cells on a bitline that has a selected cell (e.g., cell 444-(2,m) on bitline 448-m). For example, if bitline 448-m has 512 memory cells, one of which is selected, the cumulative leakage of 511 poorly deselected memory cells will deflect the bitline 448-m potential, thereby reducing the available sense signal. A similar requirement to adequately reverse bias the unselected memory cells occurs with either the FET based or bipolar based switching element shown in FIGS. 7 and 8, respectively. In the case of a FET-based switching element, the gate to source potential must be well below the FET threshold including any body effects. In the case of the bipolar-based switching element, the base-emitter diode must be adequately reverse biased to prevent conduction.

An example of voltage bias conditions and current conditions for diode based PCM devices as shown in FIGS. 15, 16 and 17 are summarized in Table 2 (Kwang-Jin Lee et al., “A 90 nm 1.8 V 512 Mb Diode-Switch PRAM With 266 MB/s Read Throughput,” IEEE J Solid-State Circuits, vol. 43, no. 1, pp. 150-162, January 2008). All voltage and current values are examples for the embodiments. A person skilled in the art would understand that other values consistent with a process technology and cell characteristic are possible.

TABLE 2
Voltage and Current Conditions for a Diode Based PCM

| | Reset Write | Set Write | Read |
|---|---|---|---|
| Voltage applied to | VDD + 2 V | VDD + 2 V | VDD + 1 V |
| Unselected W/L | | | |
| Voltage applied to | 0 V | 0 V | 0 V |
| Selected W/L | | | |
| Condition of | Floating | Floating | Floating |
| Unselected B/L | | | |
| Current flowing through | I_Reset | I_Set | I_Read |
| Selected B/L | | | |

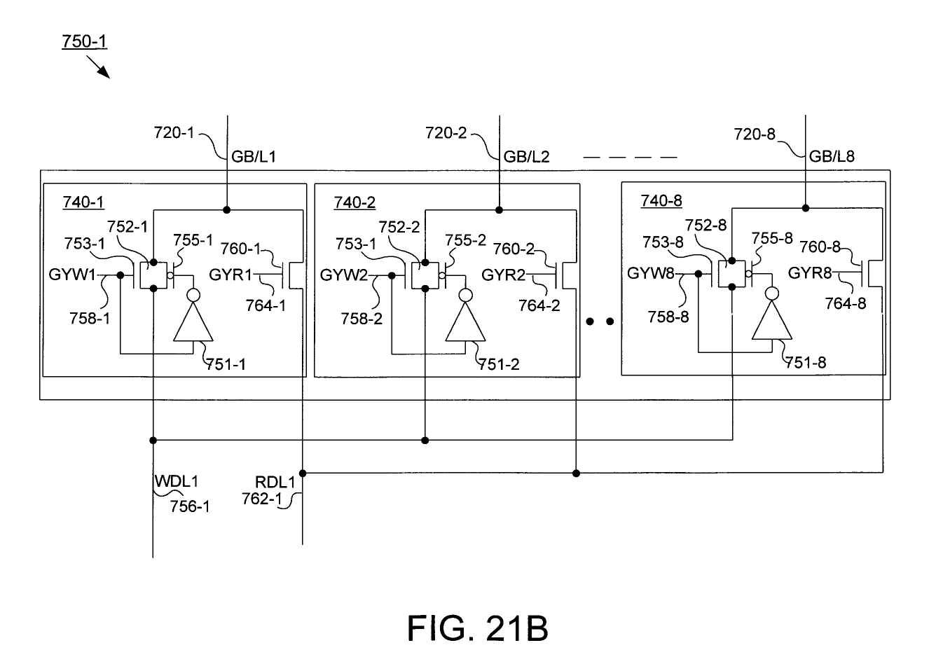

FIG. 18 depicts a bank architecture of a PCM device according to an embodiment of the present invention. Referring to FIG. 18, a bank architecture 500 includes a plurality of PCM cell sub-arrays. The particular example shown in FIG. 18 has four sub-arrays 542-1-542-4 and an eight-bit data path (or a main data line) 536 for main data MDL [7:0]. The first sub-array 542-1 is allocated to I/O 0 & 1 and provides MDL[0:1]. The second sub-array 542-2 is allocated to I/O 2 & 3 and provides MDL[2:3]. The third sub-array 542-3 is allocated to I/O 4 & 5 and provides MDL[4:5]. The fourth sub-array 542-4 is allocated to I/O 6 & 7 and provides MDL[6:7]. The PCM cell sub-arrays have a similar circuit structure to that of FIG. 15. Each sub-array has k wordlines (rows) and j bitlines (columns). At each of cross points of rows and columns, a PCM cell is connected. In the particular example shown in FIG. 18, each of PCM sub-arrays 1-4, 542-1-542-4, has j bitlines 548-1-548-j and k wordlines W/L1-W/Lk, 552-1-552-k and the total memory cells in one PCM cell sub-array are (j x k), each of j and k being an integer. For example, j and k are 1024 and 512, respectively. A person skilled in the art would understand that j and k are not limited.

The bitlines B/L1-B/Lj, 548-1-548-j, correspond to the bitlines 448-1-448-j of FIG. 15. The wordlines W/L1-W/Lk, 552-1-552-k, correspond to the wordlines 452-1-452-k of FIG. 15.

The bank architecture 500 includes a row decoder 516 connected to the k wordlines “W/L1” 552-1-“W/Lk” 552-k. The row decoder 516 selects one of the rows (e.g., wordlines) 552-1-552-k,k being, for example, 512. The bank architecture 500 includes four local column selectors (LCSs) 518-1-518-4, four global column selectors (GCS) 522-1-522-4, four write driver and sense amplifiers 526-1-526-4, a 64-bit register 530, an 8:1 multiplexor (MUX) and demultiplexor (DMUX) 534. The local column selectors 518-1-518-4 select 128 bits from the j bitlines in the sub-arrays 542-1-542-4, respectively. The four global column selectors 522-1-522-4 select 16 bits from the 128 bits selected by the local column selectors 518-1-518-4, respectively. The four local column selectors 518-1-518-4 are connected to the global column selectors 522-1-522-4 through 128-bit data paths 520-1-520-4, respectively.

Each of the four write driver and sense amplifiers writes 16 bits of data through the global column selector and senses 16 bits of data through the global column selector. The write driver and sense amplifiers 526-1-526-4 are connected to the global column selectors 522-1-522-4 through 16-bit data paths 524-1-524-4, respectively. Also, the write driver and sense amplifiers 526-1-526-4 are connected to the register 530 through 16-bit data paths 528-1-528-4, respectively.

The 64 bit register 530 receives two bits of data from each of the four write driver and sense amplifiers 526-1-526-4 and receives four groups of two bits of data from the multiplexor (MUX) and demultiplexor (DMUX) 534 through two-bit data paths 532-1-532-4. The multiplexor (MUX) and demultiplexor (DMUX) 534 sends and receives eight bits MDL[7:0] through an eight-bit data path 536.

The row decoder 516 receives a plurality of pre-row-decoder outputs “Xq”, “Xr” and “Xs” provided by pre-row decoders (not shown). A plurality of (m) local column selection signals Y1, Y2, Ym are commonly provided to the local column selectors 518-1-518-4. A plurality of (u) write global column selection signals GYW1-GYWu and a plurality of (u) read global column selection signals GYR1-GYRu are commonly provided to the global column selectors 522-1-522-4 during a write operation and during a read operation, respectively. For example, m and u are eight and 128, respectively, but not limited.

While the particular example shown in FIG. 18 includes four local column selectors, four global column selectors and four write driver and sense amplifiers, it would appear that the numbers of them are not limited. The bits of the write global column selection signals and the read global column selection signals are not limited. A person skilled in the art would understand that other data bits and word length are possible.

The data paths 520-1-520-4, 524-1-524-4, 528-1-528-4 and 532-1-532-4 include communication lines, e.g., global bitlines, data write and data read lines.

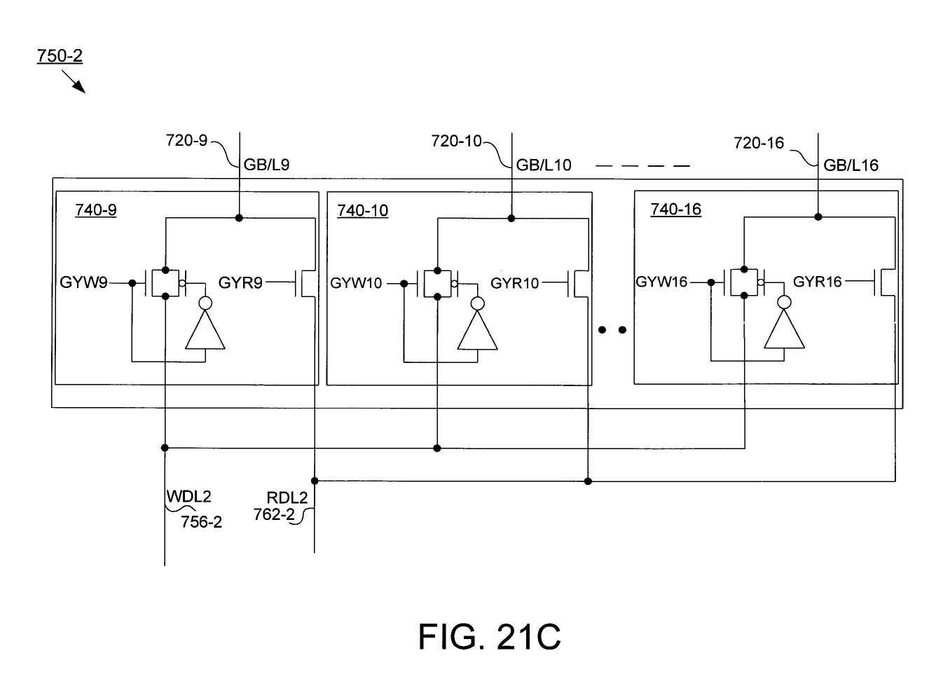

FIG. 19 shows a high level PCM device architecture according to an embodiment of the present invention. Referring to FIG. 19, a high level PCM device architecture includes eight banks 600-1-600-8, each bank being configured as shown in FIG. 18. The eight banks 600-1-600-8 have MDL[7:0] ports 636-1-636-8, respectively, that are connected to a bank multiplexor (MUX) and demultiplexor (DMUX) 642. The multiplexor (MUX) and demultiplexor (DMUX) 642 selects one of the eight ports 636-1-636-8 to communicate with an I/O buffer 644 through an eight-bit data path 638. The I/O buffer 644 drives and receives eight bit data through bus 646 (DQ7-DQ0). Each of the ports 636-1-636-8 is connected to the eight-bit data path 536 for MDL[7:0] as shown in FIG. 18.

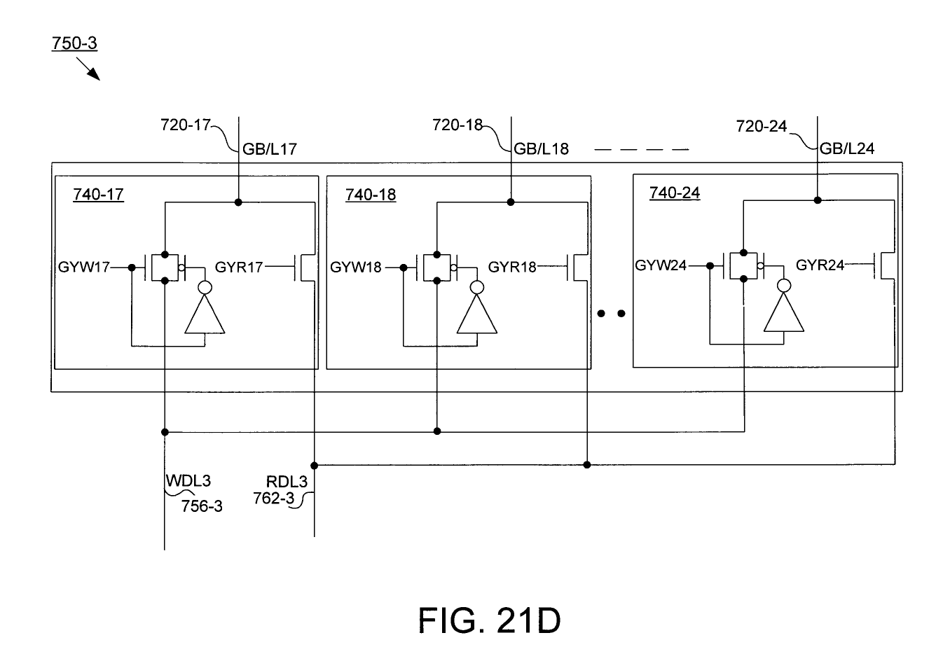

FIG. 20 shows an example of one of the local column selectors (e.g., the first local column selector 518-1) shown in FIG. 18. Referring to FIG. 20, the first local column selector 518-1 is connected to the corresponding PCM cell sub-array 1, 542-1, through the j local bitlines “B/L1” 548-1-“B/Lj” 548-j and the global column selector 522-1 through the 128 global bitlines “GB/L1” 720-1-“GB/L128” 720-128 that correspond to the data path 520-1 shown in FIG. 18.

The local column selector 518-1 includes a plurality of (u) local column decoders 700-1-700-u, which have the same circuit structure, u being an integer, for example 128. For example, the first column decoder 700-1 has a plurality of (m) NMOS bitline discharge transistors 702-1-702-m,m being an integer, for example eight. The drains of the transistors 702-1-702-m are connected to the respective bitlines “B/L1” 548-1-“B/L8” 548-8. The gates of the transistors 702-702-m are commonly connected to a discharge signal input 704 to which a bitline discharge signal “DISCH_BL” is fed to perform bitline discharge. The sources of the transistors 702-1-702-m are connected to the ground.

The local column decoder 700-1 further includes a plurality of (m) NMOS column select transistors 706-1-706-m, the sources of which are connected to respective ones of local bitlines 548-1-548-m (i.e., 548-8). The gates of the transistors 706-1-706-m are connected to local column select inputs 712-1-712-m, respectively, to which the local column selection signals Y1, Y2, Ym are fed to perform local column selection operation. The drains of the transistors 706-1-706-m are commonly connected to the corresponding global bitline “GB/L1” 720-1.

Similarly, the u-th column decoder 700-u has a plurality of (m) NMOS bitline discharge transistors 702-1-702-m, the drains of which are connected to the respective bitlines “B/L((j-m)+1)” 548-((j-m)+1)”-“B/L8j”” 548-j”. The gates of the transistors 702-702-m are commonly connected to a discharge signal input 704 to which the bitline discharge signal “DISCH_BL” is fed to perform bitline discharge. The sources of the transistors 702-1-702-m are connected to the ground.

The local column decoder 700-u further includes a plurality of (m) NMOS column select transistors 706-1-706-m, the sources of which are connected to respective ones of local bitlines “B/L((j-m)+1)” 548-((j-m)+1)”-“B/L8j“ ” 548-j″. The gates of the transistors 706-1-706-m are connected to local column select inputs 712-1-712-m, respectively, to which the local column selection signals Y1, Y2, Ym are fed to perform local column selection operation. The drains of the transistors 706-1-706-m are commonly connected to the corresponding global bitline “GB/L128” 720-128.

The local column decoders 700-1-700-u further include NMOS transistors 720-1-720-u, the drains of which are connected to the global bitline “GB/L1” 720-1-“GB/L128” 720-128, respectively. The sources of the transistors 720-1-720-u are connected to the ground. The gates of the NMOS transistors 720-1-720-u are commonly connected to a discharge input 722 to which a common global bitline discharge signal “DISCH_GBL” is fed. The common global bitline discharge signal “DISCH_GBL” provided by a discharge signal source (not shown) to control the discharge of the global bitlines 720-1-720-128.

Referring to the figures, in the write operation phase, when the cell 444-(2,m) is being written as shown in FIG. 16, the bitline discharge signal “DISCH_BL” fed to the input 704 and the common global bitline discharge signal “DISCH_GBL” fed to the input 722 are “low” to deactivate the respective discharge paths (which include the beltlines and global bitlines). In response to the local column selection signals Y1, Y2, Ym fed to the local column select inputs 712-1, 712-2, 712-m, selection of bitline is performed.

In a case where only Ym is “high”, the gates of the transistors 706-1, 706-2, in each of the local column decoders 700-1-700-u is “low”, so that the column select transistors 706-1, 706-2, are deactivated and bitlines 548-1, 548-2, are floating. The gate of the transistors 706-m of the local column decoders 700-1-700-u are held “high” and the column select transistors 706-m are activated. The global bitlines 720-1-720-128 are connected to the 128 local bitlines 548-8, . . . , 548-j (by every eight bitlines) that are associated with the memory cells through the activated transistors 706-m of the local column decoders 700-1-700-u. Similarly, different logic state of the local column selection signals Y1, Y2, Ym causes different bitlines to be selected to select or identify memory cells.

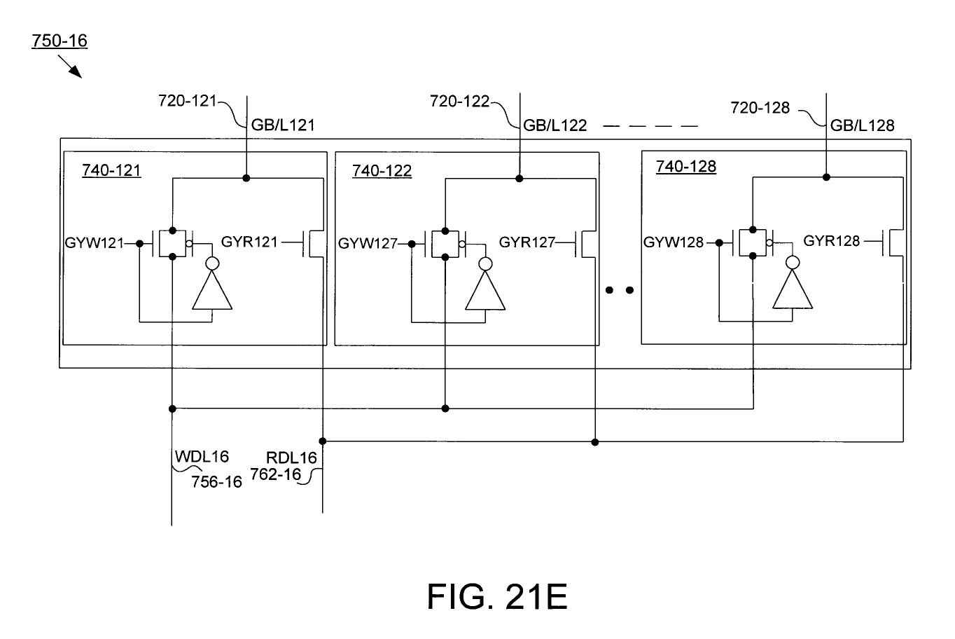

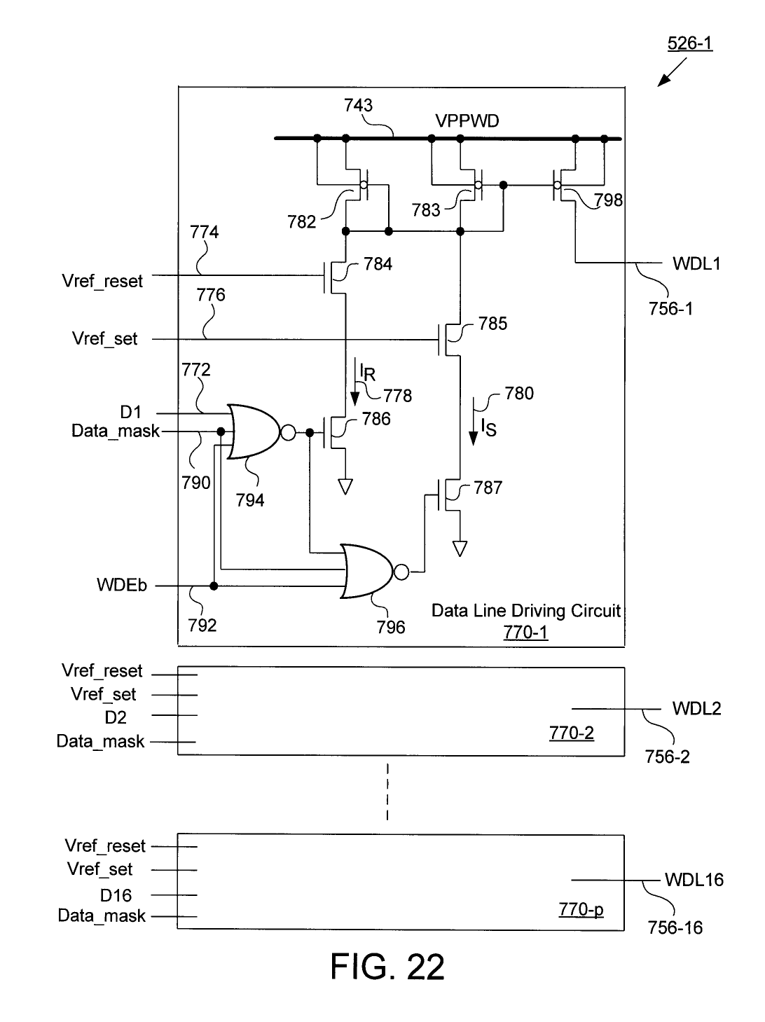

FIG. 21A shows an example of one of the global column selectors (e.g., the global column selector 522-1) shown in FIG. 18. Referring to FIG. 21A, the global column selector 522-1 has a plurality of ((t): e.g., 16) global column decoders 750-1-750-16. The global column selector 522-1 is connected to the corresponding local column selector 518-1 thorough the global bitlines “GB/L1” 720-1-“GB/L128” 720-128. The global column selector 522-1 is also connected to the corresponding write driver and sense amplifier 526-1 through common write data lines “WDL1” 756-1-“WDL16” 756-16 and common read data lines “RDL1” 762-1-“RDL16” 762-16. The other global column selectors 522-2-522-4 have the same circuit structure as that of the global column selector 522-1.

FIG. 21B shows an example of one of the global column decoders (e.g., the global column decoder 750-1) shown in FIG. 21A. Each of the global column decoders 750-1-750-16 has a plurality of ((w); e.g., eight) decoding circuits. Referring to FIG. 21B, the global column decoder 750-1 has eight decoding circuits 740-1-740-8, each of which includes write path control circuitry and read path control circuitry. The write path control circuitry includes a full CMOS transmission gate and an inverter. The read path control circuitry includes an NMOS transistor. The eight decoding circuits 740-1-740-8 share a write data line (WDL) and a read data line (RDL).

For example, the first decoding circuit 740-1 includes a full CMOS transmission gate 752-1 between the global bitline “GB/L1” 720-1 and the first write data line “WDL1” 756-1. The transmission gate 752-1 is formed by an NMOS transistor 753-1 in parallel with a PMOS transistor 755-1, both located between the global bit line 720-1 and the write data line “WDL1” 756-1. The gate of NMOS transistor 753 is connected to an input 758-1 to which a write global column select signal “GYW1” is fed. The input 758-1 is connected via an inverter 751-1 to the gate of the PMOS transistor 755-1. The transmission gate 752-1 is controlled by the write global column select signal GYW1. The transmission gate 752-1 and the inverter 751-1 form the write path control circuitry.

The first decoding circuit 740-1 includes an NMOS transistor 760-1 for data read between the global bitline 720-1 and the first common read data line “RDL” 762-1. The gate of the NMOS transistor 760-1 is connected to a read global signal input 764-1 to which the read global column select signal GYR1 is fed. The NMOS transistor 764-1 forms the read path control circuitry.

The other decoding circuits 740-2-740-8 have the same circuit structure as that of the decoding circuit 740-1 and perform the same function. The second decoding circuit 740-2 includes a full CMOS transmission gate 752-2 between the global bitline “GB/L2” 720-2 and the common write data line “WDL1” 756-1. The transmission gate 752-2 is formed by an NMOS transistor 753-2 in parallel with a PMOS transistor 755-2, both located between the global bit line 720-2 and the write data line “WDL1” 756-1. The gate of NMOS transistor 753-2 is connected to an input 758-2 to which the write global column select signal “GYW2” is fed. The input 758-2 is connected via an inverter 752-2 to the gate of the PMOS transistor 755-2. The transmission gate 752-2 is controlled by the write global column select signal GYW2. The second decoding circuit 740-2 includes an NMOS transistor 760-2 for data read between the global bitline 720-2 and the read data line “RDL” 762-1. The gate of the NMOS transistor 760-2 is connected to a read global signal input 764-2 to which the read global column select signal GYR2 is fed. The decoding circuit 740-2 is used to pass the write data controlled by GYW2 or the read data controlled by GYR2.

Similarly, the eighth decoding circuit 740-8 includes a full CMOS transmission gate 752-8 between a global bitline “GB/L8” 720-8 and the common write data line “WDL1” 756-1. The transmission gate 752-8 is formed by an NMOS transistor 753-8 in parallel with a PMOS transistor 755-8, both located between the global bit line 720-8 and the write data line “WDL1” 756-1. The gate of NMOS transistor 753-8 is connected to an input 758-8 to which the write global column select signal “GYW8” is fed. The input 758-8 is connected via an inverter 752-8 to the gate of the PMOS transistor 755-8. The transmission gate 752-8 is controlled by the write global column select signal GYW8. The eighth decoding circuit 740-8 includes an NMOS transistor 760-8 for data read between the global bitline 720-8 and the read data line “RDL” 762-1. The gate of the NMOS transistor 760-8 is connected to a read global signal input 764-8 to which the read global column select signal GYR8 is fed. The decoding circuit 740-8 is used to pass the write data controlled by GYW8 or the read data controlled by GYR8.

FIG. 21C shows the second global column decoder 750-2 shown in FIG. 21A. Referring to FIG. 21C, the second global column decoder 750-2 has eight decoding circuits 740-9-740-16. The eight transmission gates of the decoding circuits 740-9-740-16 are connected between the corresponding global bitlines GB/L9-GB/L16, 720-9-720-16, and the second common write data line WDL2, 756-2. The eight data read NMOS transistors of the decoding circuits 740-9-740-16 are connected between the corresponding global biltines GB/L9-GB/L16, 720-9-720-16 and the second common read data line RDL2, 762-2. The decoding circuits 740-9-740-16 are controlled by the write global column select signals GYW9-GYW16 and the read global column select signals GYR9-GYR16 to pass the write data and the read data, respectively, between the second write data line WDL2, 756-2.

FIG. 21D shows the third global column decoder 750-3 shown in FIG. 21A. Referring to FIG. 21D, the third global column decoder 750-3 has eight decoding circuits 740-17-740-24. The eight transmission gates of the decoding circuits 740-17-740-24 are connected between the corresponding global bitlines GB/L17-GB/L24, 720-17-720-24, and the third common write data line WDL3, 756-3. The eight data read NMOS transistors of the decoding circuits 740-17-740-24 are connected between the corresponding global biltines GB/L17-GB/L24, 720-17-720-24 and the third common read data line RDL3, 762-3. The decoding circuits 740-17-740-24 are controlled by the write global column select signals GYW17-GYW24 and the read global column select signals GYR17-GYR24 to pass the write data and the read data, respectively, between the second write data line WDL3, 756-3.

FIG. 21E shows the sixteenth global column decoder 750-16 shown in FIG. 21A. Referring to FIG. 21E, the sixteenth global column decoder 750-16 has eight decoding circuits 740-121-790-128. The eight transmission gates of the decoding circuits 740-121-740-128 are connected between the corresponding global bitlines GB/L121-GB/L128, 720-121-720-128, and the third common write data line WDL16, 756-16. The eight data read NMOS transistors of the decoding circuits 740-121-740-128 are connected between the corresponding global biltines GB/L121-GB/L128, 720-121-720-128 and the sixteenth common read data line RDL16, 762-16. The decoding circuits 740-121-740-128 are controlled by the write global column select signals GYW121-GYW128 and the read global column select signals GYR128-GYR128 to pass the write data and the read data, respectively, between the second write data line WDL16, 756-16.

In the example, the write global column select signals GYW1-GYW128 and the read global column select signals GYR1-GYR128 are fed to the respective data write circuitry and the data read circuitry. In another example, the write global column select signals GYW1-GYW128 can be 16 groups of eight signals (GYW1-GYW8) and the read global column select signals GYR1-GYR128 can be 16 groups of eight signals (GYR1-GYR8). Each of the 16 groups of GYW1-GYW8 and GYR1-GYR8 can be commonly fed to the respective ones of the 16 global column decoders 750-1-756-16. In the another example, selection or designation of one of the WDL1-WDL16 and RDL1-RDL16 is necessary.

The global column decoder 750-1 is used to select one of the groups of bits from local column selectors 518-1 and to provide selection of either write data controlled by GYW1 758-1-I or the read data controlled by GYR1-8. In one preferred embodiment, only one of the GYW and GYR control signals is selected at one time. In another embodiment, both GYW1 and GYR control signals are selected at the same time to use the global column selector (e.g., the global column selector 522-1) as a data bypass useful for testing purposes to control and observe data flow independent of the functionality of the memory arrays.

The global column selectors shown in FIGS. 21A-21E are advantageous for architectures that share a common READ and WRITE data bus (“RDL” and “WDL”).

The other global column decoders 750-2-750-16 have the same circuit structure as that of the global column decoder 750-1. Each global column decoder has eight decoding circuits and each decoding circuit includes a full CMOS transmission gate and a data read NMOS transistor as shown in FIG. 21B.

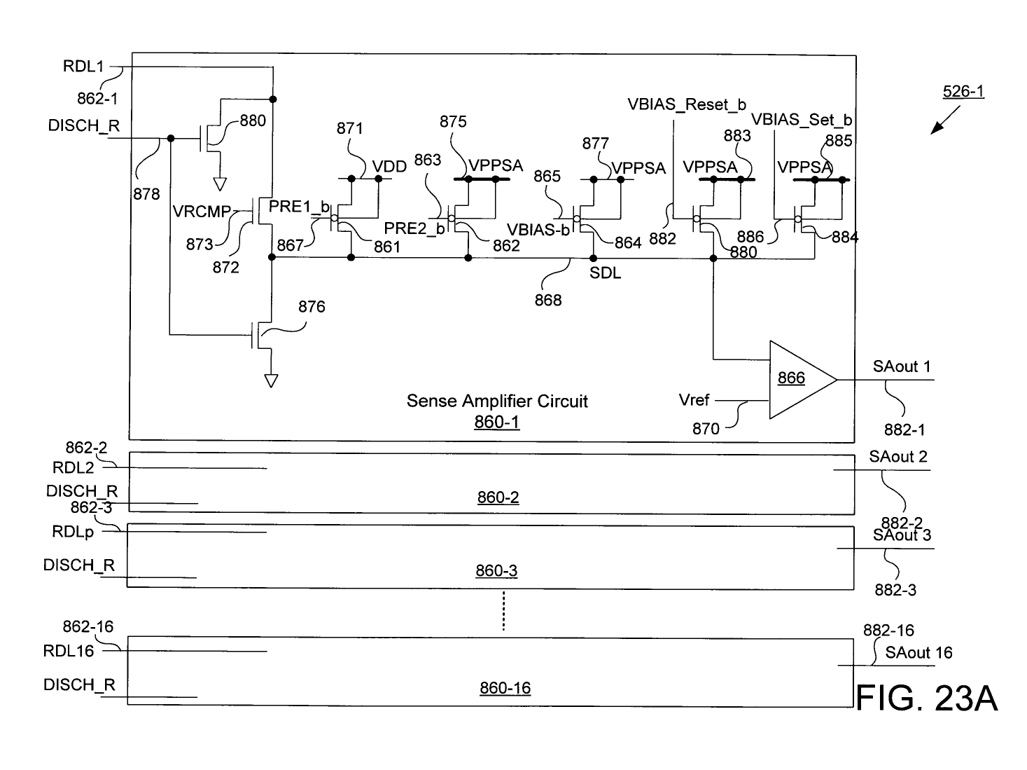

FIG. 22 shows an example of a write driver (WD) portion of one write driver and sense amplifier shown in FIG. 21 (e.g., the write driver and sense amplifier 526-1). The other write driver and sense amplifiers have the same circuit structure.

The write driver portion of the write driver and sense amplifier 526-1 receives the input data “Data_in” from the register 530 shown in FIG. 18. The write driver portion is connected to the corresponding global column selector through the write data lines “WDL1”-“WDL16” 756-1-756-16 shown in FIG. 21A.

Referring to FIG. 22, the write driver portion of the write driver and sense amplifier 526-1 includes 16 data line driver circuits 770-1-770-16. The data line driver circuits have the same circuit structure. For example, in the data line driving circuit 770-1, in response to a data input signal “D1” 772 and control voltages “Vref_reset” 774 and “Vref_set” 776, two currents “I_{R}” 778 and “I_{S}” 780 flow. The current 778 flows through the transistors 782, 784 and 786 and is gated by transistors 784 and 786 by several conditions. Firstly, the Vref_reset control voltage 774 must be “high” to enable RESET programming. Secondly, the D1 signal 772 must be low (or at a logical “0” state as shown in Table 1). Finally, both the Data_mask signal 790 and an inverted write data enable (WDEb) 792 must be “low”. The WDEb signal 792 generally enables the data line driver circuit. The Data_mask signal 790 enables the data line driver circuit when the contents read from a memory (e.g., write verify) do not match the input data. In other words, a previous write operation needs to be repeated. When all of these conditions are met, transistors 784 and 786 are both on and current “I_{R}” 778 is allowed to flow. The control voltages “Vref_reset” and “Vref_set” and the inverted write data enable (WDEb) 792 are provided by control circuitry (not shown).

The current “I_{S}” 780 flows through the transistors 783, 785 and 787 and is gated by transistors 785 and 787 by two conditions. Firstly, the control voltage Vref_set 776 must be “high” to enable SET programming. Secondly, the D1 signal 772 must be “high” (or at a logical “1” state as shown in Table 1). Finally, both the Data_mask signal 790 and the inverted write data enable (WDEb) 792 must be “low”. When all of these conditions are met, transistors 785 and 787 are both on and current “I_{S}” 780 is allowed to flow. Separate control of the Vref_reset 774 and Vref_set 776 control voltages is used because the RESET and SET programming intervals (described as the Write Pulse in Table 1) are required to properly alter the programming volume 130 shown in FIG. 4B. The D1 signal 772 controls the transistors 786 and 787 through a pair of NOR gates 794 and 796, respectively. Specifically, the D1 signal 772 is inverted by NOR gate 794 to turn on transistor 786 when the D1 signal 772, Data_mask 790 and WDEb 792 are “low”. NOR gate 794 also buffers the transistor 786. In the data line driving circuit 770-1 with the transistor 786 connected in parallel do not impose an excessive capacitive load on the control signal, which would reduce the transition time of the D1 signal 772.

The D1 signal 772 is inverted by the NOR gate 794 so that its inverted output signal is fed to a second NOR gate 796, the output of which controls the gate of transistor 787. The transistor 787 is turned on in response to a “high” voltage on the D1 signal 772. With reference to Table 1 and FIGS. 4A, 4B, a “high” voltage on the D1 signal 772 corresponds to a logical “1” state or the SET state. A “low” voltage on the D1 signal 772 corresponds to a logical “0” state or the RESET state. A current mirror formed by PMOS transistors 782, 783 and 798 mirrors the current “I_{R}” 778 to the write data line “WDL1” 756-1 during operation of writing the RESET state. A current mirror formed by the PMOS transistors 783, 782 and 798 mirrors the current “I_{S}” 780 to the write data line “WDL1” 756-1 during operation of writing the SET state. The resultant I_Set and I_Reset are, for example, about 0.2 mA and 0.6 mA, respectively.

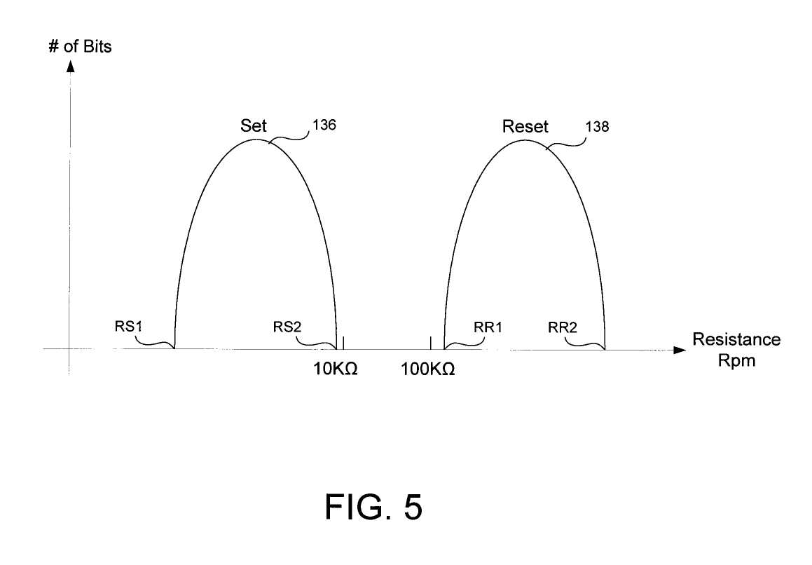

The data line driving circuit 770-1 provides a higher current for RESET shown as I_Reset and a lower current for the SET operation shown as I_Set in FIG. 3. The currents of the RESET and SET operations are defined by the ratio of the size of the transistors 784 and 785.

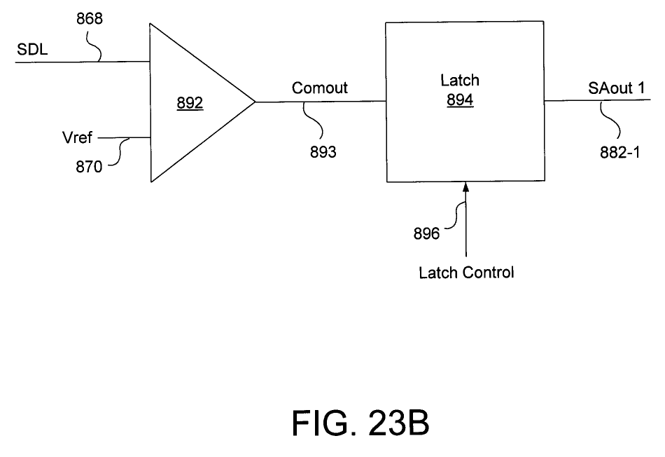

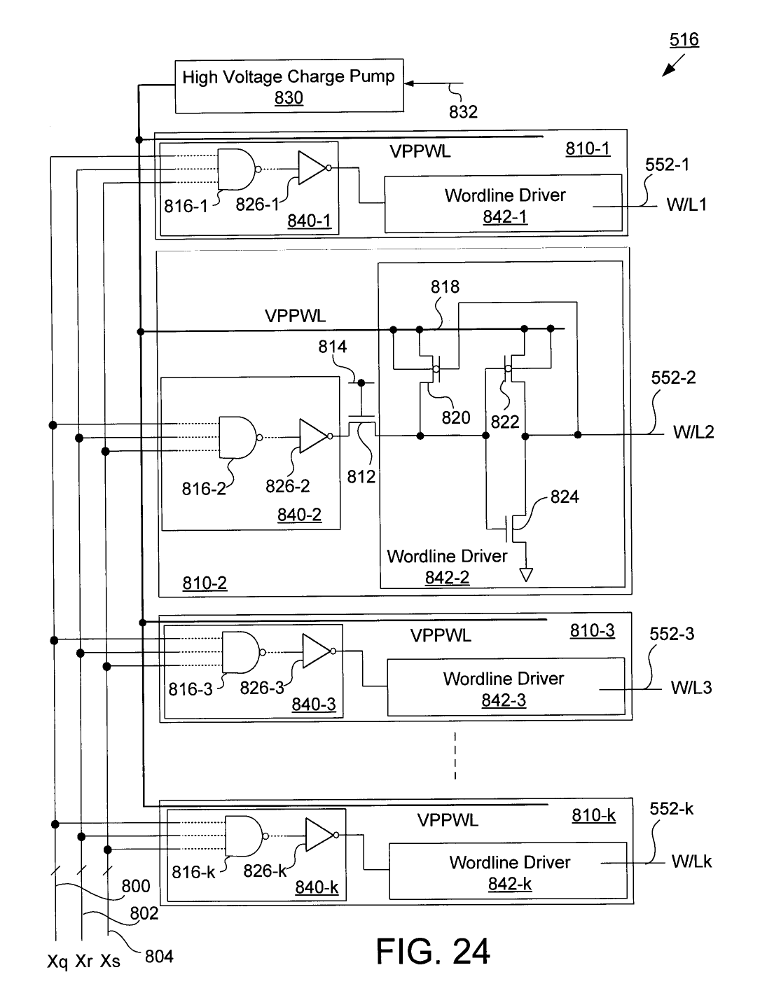

FIG. 23A shows an example of a sense amplifier (S/A) portion of one write driver and sense amplifier (e.g., the write driver and sense amplifier 526-1) shown in FIG. 18. The sense amplifier portion of the write driver and sense amplifier 526-1 receives the read data from the global column selector shown in FIG. 18 and provides the register 530 through the read data lines “RDL1”-“RDL16” shown in FIG. 21A. Referring to FIG. 23A, the sense amplifier portion of the write driver and sense amplifier 526-1 includes 16 sense amplifier circuits 860-1-860-16. Details of the sense amplifier circuit 860-1 are shown in FIG. 23A. The other sense amplifier circuits have the have the same circuit structure as that of the first sense amplifier circuit 860-1.

The sense amplifier circuit 860-1 reads data through a bitline from a memory of PCM cell array (e.g., the PCM cell sub-array 542-1 in FIG. 18). A bitline within the memory array is selected by the local column selector 518-1. The global column selector 522-1 further selects 16 bits from the local column selector 518-1 and the data passes from the PCM cell sub-array 542-1 to the sense amplifier 860-1 on the read data line “RDL” 762-1 shown in FIG. 23.

A PMOS bitline precharge transistor 861 is controlled by “PRE1_b” 867 with a voltage source equal to VDD. Another PMOS bitline precharge transistor 862 is controlled by “PRE2_b” 863 with a voltage source equal to VPPSA, where VPPSA is typically greater than VDD. A PMOS bitline bias transistor 864 is controlled by “VBIAS_b” 865 with a voltage equal to VPPSA. Transistor 864 provides the reference resistance for read Rref shown in FIG. 13. A PMOS bitline bias transistor 880 is controlled by VBIAS_Reset_b 882 with a voltage source equal to VPPSA to a voltage line 883. Transistor 880 provides the reference resistance for reset verify RR1 shown in FIG. 13. A PMOS bitline bias transistor 884 is controlled by VBIAS_Setb 886 with a voltage source equal to VPPSA to a voltage line 885. Transistor 884 provides the reference resistance for set verify RS2 shown in FIG. 13.

The drains of the PMOS transistors 861, 862, 864, 880 and 884 are commonly connected to a sensing data line “SDL” 868. A differential voltage amplifier (and comparator) 866 has two inputs one of which is connected to SDL 868 and the other of which is connected to a reference signal input 870 to which a reference voltage “Vref” is applied. An NMOS voltage clamp transistor 872 is between RDL 762-1 and the SDL 868 and is controlled by “VRCMP” 873. An NMOS transistor 876 is controlled by “DISCH_R” 878 for SDL 868 discharge. An NMOS transistor 880 is controlled by “DISCH_R” 878 to discharge RDL 762-1. The discharge transistors 876 and 880 discharge the SDL 868 and RDL 762-1, respectively, in preparation for a READ operation. In one example, the NMOS transistor 880 is larger than the NMOS transistor 876 to discharge RDL 762-1 at the same rate as SDL 868, RDL 762-1 having a higher capacitive loading than SDL 868.

The two precharge transistors 861 and 862 provide for a more gradual precharge rate on the bitlines. Advantageously, the two slope precharging approach reduces the burden on a charge pump used to supply the VPPSA voltage. VPPSA is boosted from VDD with a charge pump. In one embodiment, VPPSA is VDD+2V. Charge pumps have limited current sourcing ability for a given area. The two stage precharge scheme first uses PRE1_b 867 to bring SDL 868 from 0V to VDD by sourcing current directly from VDD. The second stage then uses PRE2_b 863, which charges SDL 868 from VDD to VPPSA using current supplied by the VPPSA charge pump. By precharging SDL to VPPSA, adequate read voltage margin for diode based PCM cells is ensured.

The bias transistor 864 provides a load current equal to the current sunk by the selected memory cell 444-(2,m) (of FIG. 17), excluding parasitic currents and converts the current drawn from the selected memory cell into a voltage on SDL 868. The amplifier 866 then compares the developed voltage on SDL 868 against the reference voltage “Vref” fed to the reference signal input 870, and drives the sense amplifier output “SAout” 882-1 high if the voltage at SDL 868 exceeds the reference voltage Vref 870.

Referring to the figures, if the memory cell 444-(2,m) is programmed to the RESET state, amorphous material 130 will be present, which will result in higher resistance between the second electrode 128 and the first electrode 124, compared to the SET state. Higher resistance will result in a larger voltage drop across the memory cell 444-(2,m) and consequently a higher voltage at SDL 868 is sensed than when the SET state is sensed.

The amplifier 866 can be replaced with read data retaining circuitry including a latch function circuit that latches the state of the sense amplifier output SAout (e.g., SAout 882-1) controlled by an additional control signal. FIG. 23B shows an example of read data retaining circuitry. Referring to FIG. 23B, the read data retaining circuitry includes an amplifier/comparator circuit 892 and a latch circuit 894 having a control signal input 896. The amplifier 866 has an amplifier/comparator circuit 892 and a latch circuit 894 having a control input 896. The amplifier/comparator circuit 892 compares the voltage developed at SDL 868 to the reference voltage Vref provided to the reference signal input 870 and provides a comparison output voltage “high” (“logic 1”) or “low” (“logic 0”) Comout 893 as a sensed result to the latch circuit 894. The latch circuit 894 latches the sensed result (“low” or “high”) in response to a latch control signal fed to the control input 896. The latched result is kept until the latch circuit 894 receives a next control signal to the input 896. The latched result is outputted as the sense amplifier output SAout 1 882-1.

In another example, the amplifier 866 includes hysteresis, so that SAout 882-1 will not toggle when the voltage at SDL 868 is equal to the reference voltage Vref fed to the reference signal input 870 during the cell data development phase 924.

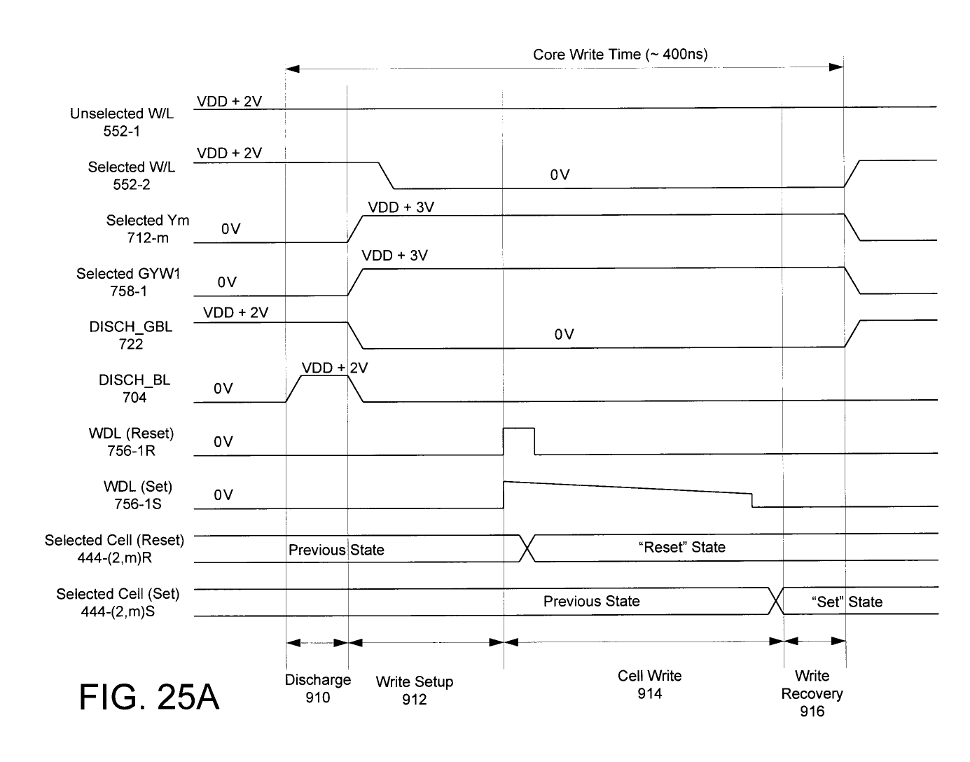

FIG. 24 shows an example of one of the row decoder 516 shown in FIG. 18. Referring to FIG. 24, the row decoder 516 has a plurality of (k) decoding circuits that are connected through the wordlines to the PCM cell memories. The particular example of the row decoder shown in FIG. 24 includes 512 decoding circuits 810-1-810-512 and each decoding circuit includes decoding logic circuitry for decoding address input signals in response to pre-row-decoder outputs and a wordline driver for providing “selected” or “non-selected” voltage to the wordline in response to the decoded address signal. The decoding logic circuitry includes a combination of logic gates. In FIG. 24, only one NAND gate and one inverter are shown for representing decoding logic circuitry. The wordline driver includes MOS transistor based driving circuitry.

Referring to FIGS. 18 and 24, in one of the decoding circuit 810-2 has three sets of pre-decoded signal inputs 800, 802 and 804 for receiving the pre-row-decoder outputs “Xq”, “Xr” and “Xs”, respectively. Each of the three pre-row-decoder outputs Xq, Xr and Xs includes address information (“1”-“8”). In this example, Xq, Xr and Xs represent addresses “001”-“512”. For example, the decoding circuit 810-2 has decoding logic circuitry 840-2 including a NAND gate 816-2 and an inverter 826-2 connected to output of the NAND gate 816-2. The decoding logic circuitry 840-2 has inputs that are connected to the pre-decoded signal inputs 800, 802 and 804. The decoding circuit 810-2 has a wordline driver 842 including a pull-up PMOS transistor 820 and a complementary circuit of PMOS transistor 822 and an NMOS transistor 824. The output of the inverter 826-2 is connected through a clamping NMOS transistor 812 to the drain of PMOS transistor 820 and the gates of PMOS transistor 822, an NMOS transistor 824. The sources of the PMOS transistors 820 and 822 are connected to a voltage line 818 to which voltage VPPWL is provided. The drains of the PMOS transistor 822 and the NMOS transistor 824 are commonly connected to the wordline “W/L1-2” 552-2 and the gate of the PMOS transistor 820.

Each of the other decoding circuits 810-1 and 810-3-810-k has the same circuit structure as that of the decoding circuit 810-2. The decoding circuit 810-1 has decoding logic circuitry 840-1 including NAND gate 816-1 and an inverter 826-1. Similarly, the decoding circuit 810-512 has decoding logic circuitry 840-k and an inverter 826-512. Each of the decoding circuits 810-1 and 810-3-810-512 has a wordline driver. The decoding circuits 810-1 and 810-3-810-512 commonly receive the pre-row-decoder outputs “Xq”, “Xr” and “Xs”. The decoding circuits 810-1 and 810-3-810-512 are connected to the wordlines “W/L1” and -“W/L512” 552-1-552-512, respectively.

The row decoder 516 is enabled by the pre-row-decoder outputs “Xq”, “Xr” and “Xs”. In the case where the wordline W/L2 is to be selected, the output of the NAND gate 816-2 is “low” and the inverter 826-2 outputs “high”. The transistor 824 is on and the wordline W/L2, 552-2 is pulled down to “low” or “0”. In the case where the wordline W/L2 is to be unselected, the output of the NAND gate 816-2 is “high” and the inverter 826-2 outputs “low”. The transistor 822 is on and the wordline “W/L2” 552-2 is pulled up to “high (VPPWL)”. Therefore, “0V” or “VPPWL” is provided to the wordline in response to the address decoding.

The decoding output of the row decoder 516 is provided to the corresponding wordline. The decoding output at the wordline is set to 0V when the memory cell connected to the wordline is selected. The decoding output is set to VPPWL at the wordline to which non-selected memory cell is connected. At the time of a wordline being unselected, the applied voltage to the selected wordline is VPPWL of the voltage line 818. The applied voltage is VDD+2V during the write operation, regardless whether the set write or the read write, as shown in FIG. 16. The applied voltage is VDD+1V during the read operation as shown in FIG. 17. Such voltages are described above in Table 2.

The voltages of VDD+2V and VDD+1V are supplied as VPPWL by a high voltage charge pump 830 in response to an operation phase signal 832 provided by the memory controller (not shown). The operation phase signal 832 indicates a write operation phase or a read operation phase. Since circuitry of the high voltage charge pump 830 is known, for example, a charge pump, its details are omitted.

The clamping transistor 812 is controlled by voltage provided to a line 814 to prevent the voltage VPPWL at the voltage line 818 from sourcing excessive voltage back to the decoding logic circuitry 840-2. For example, the voltage at the line 814 is VDD that is lower than VPPWL. The pull-up transistor 820 is activated when “W/L2” 552-2 is “low”. This ensures that the “low” level at “W/L2” 552-2 used to select a memory cell 444-(2,m) on a row to be read (e.g., 552-1 in FIG. 16) or the memory cell 444-(2,m) on a row to be written (e.g., the wordline 552-1 in FIG. 17) will be more immune to noise coupling from adjacent.

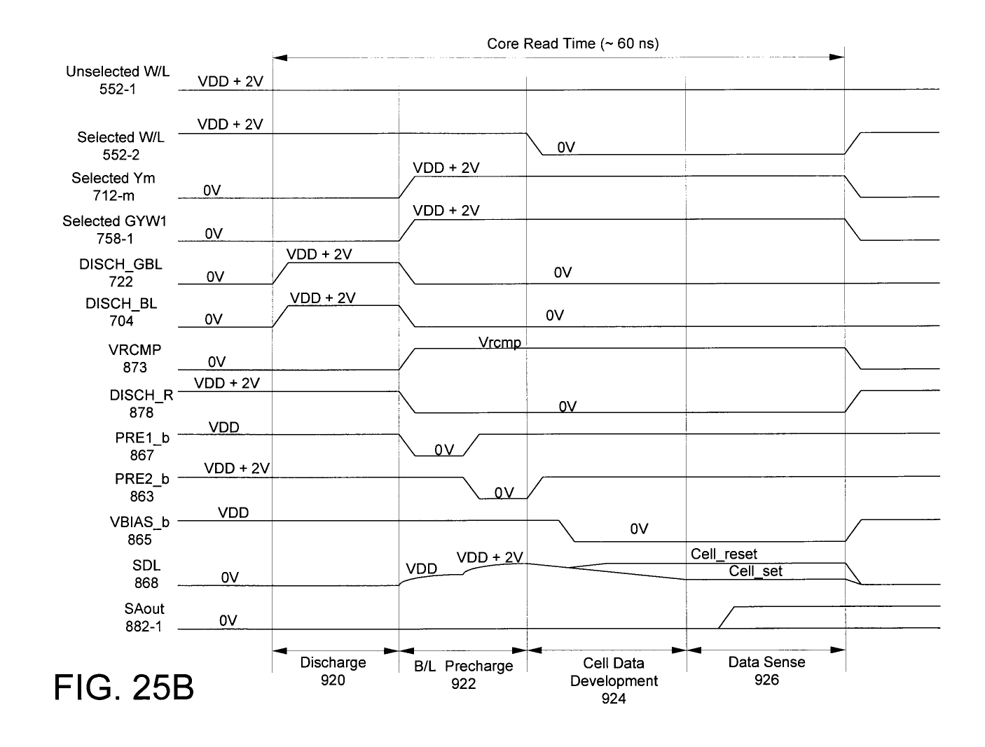

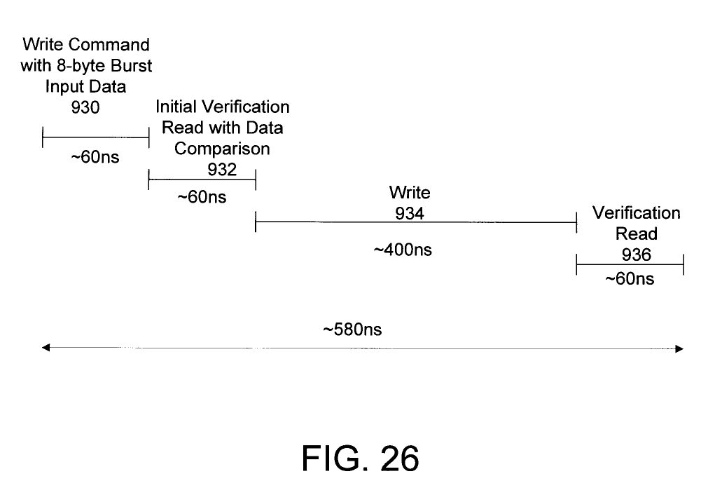

FIG. 25A shows a WRITE-operation timing diagram including four phases, namely “Discharge” 910, “Write Setup” 912, “Cell Write” 914 and “Write Recovery” 916. During the Discharge phase 910, local bitlines and global bitlines are discharged to 0V. This is accomplished by raising the DISCH_BL 904 and DISCH_GBL 922 signals to VDD+2V. Raising DISCH_BL 904 and DISCH_GBL 922 to a voltage greater than VDD provides more drive current to discharge the bitline and global bitline, respectively. In another embodiment, DISCH_BL 904 and DISCH_GBL 922 are only raised to VDD and the Discharge phase 910 is extended for longer discharge time.

In the following description, the bitlines 548-1-548-j as shown in FIGS. 18 and 20 and the corresponding bitlines 448-1-448-j as shown in FIGS. 15-17 are interchangeable. Also, the wordlines 552-1-552-k as shown in FIGS. 18 and 24 and the corresponding wordlines 452-1-452-k as shown in FIGS. 15-17 are interchangeable.

Referring to the figures, during the Discharge phase 910, the wordlines (e.g., wordlines 552-1 and 552-3 through 552-k) are unselected or deselected by applying VDD+2V. Although the wordlines need only be raised to approximately one diode threshold above the bitline (e.g., the bitline 548-m) potential to prevent the diode based memory cells from conducting, raising the wordlines to VDD+2V ensures that the memory cells 444-(2,m) shown in FIG. 16 will not conduct current while the bitlines are discharging. The bitlines (548-1-548j in FIG. 19) and the global bitlines (720-1-720-128 in FIG. 19) are also discharged by applying VDD+2V to DISHC_BL 704 and DISCH_GBL 722 respectively.

Referring to the figures, during the Write Setup phase 912, the local bitlines and global bitlines are allowed to “float” by deactivating DISCH_BL 704 and DISCH_GBL 722, respectively. A floating bitline means the bitline potential is not driven by a low impedance source (e.g., a driver) but can significantly maintain the previously potential with the parasitic capacitance of the bitline. The write driver output WDL 756-1 shown in FIG. 21A is connected to a selected wordline (e.g., 552-2, 452-2 in FIG. 15) to select the diode based memory cell 444-(2,m) to be written. The bitline 548-m is selected by Ym 712-m in a local column selector and GYW1 758-1 in a global column selector. The voltages applied to Ym 712-m and GYW1 758-1 are VDD+3V to ensure the full voltage range (e.g., VPPWD) of the WDL signal 756-1 (shown in FIG. 21A) can pass from the write driver data line driving circuit 770-1 of the write driver and sense amplifier 526-1 to the memory cell 444-(2,m).

Referring to the figures, during the Cell Write phase 914, the cell 444-(2,m) is written to the RESET state by fast quenching or to the SET state by slow quenching, respectively. The data line driving circuit 770-1 provides the proper write current in accordance with the D1 signal 772, Data-mask signal 790, WDEb 792 and control signals 774 and 776 shown in FIG. 22. To write a RESET state to the memory cell 444-(2,m)R a short pulse is provided, shown as 756-1 in FIGS. 25A and 132 in FIG. 3. To write a SET state to the memory cell 444-(2,m)S a longer pulse is provided, shown as 756-1S in FIGS. 25A and 134 in FIG. 3.

During the Write Recovery phase 916, the Chalcogenide compound 130 in FIG. 4B is given additional time to crystallize and cool. Following the Write Recovery phase 916, the selected wordline 552-2 and the global bitline discharge signal “DISCH_GBL return to VDD+2V. The local column select Ym 712-m and global column select GYW1 758-1 are turned off.

The operations of the Discharge 910, Write Setup 912, Cell Write 914 and Write Recovery 916 take “core write time”, which is, for example, approximately 400 ns.

FIG. 25B shows a READ operation timing diagram including four phases, namely “Discharge” 920, “B/L Precharge” 922, “Cell Data Development” 924 and “Data Sense” 926. During the Discharge phase 920, the local bitlines and global bitlines are discharged by the DISCH_BL 704 and DISCH_GBL 722 signals, similar to the WRITE-operation shown in FIG. 25A. In addition, RDL 762-1 and SDL 868 signals are discharged by applying VDD+2V to the DISCH_R 878 signal shown in FIG. 23A.

Referring to the figures, during the bitline-precharge phase 922, the local and global column select transistors, are turned on by the selected column select line Ym 712-m and the global column select line GYW1 758-1, respectively. VRCMP 873 (shown in FIG. 23A) is set to a “VDD-rcmp” voltage level, which will cause the clamping transistor 872 to limit the voltage that can be passed from RDL 762-1 to SDL 868 to prevent the amplifier 866 from saturating and limiting recovery time. In one embodiment, VDD-rcmp is set to VDD+3V thereby allowing a voltage of VDD+3V less the threshold of the clamping transistor 872 to be passed from the read data line “RDL1” 762-1 to SDL 868. The SDL 868 is precharged to VDD+2V with a two-step precharge operation, first to VDD (e.g. 1.8V) and then to VDD+2V by precharge signals PRE1_b 867 and PRE2_b, 863, respectively.

Referring to the figures, during the Cell Development phase 924, the selected wordline 552-2 is biased to 0V. The bias transistor 864 for SDL 868 is enabled (shown in FIG. 23A). During this period the selected memory cell 444-(2,m) will draw current and cause SDL 868 to change potential in accordance with the programmed state in the memory cell 444-(2,m).

During the Data Sense phase 926, the sense amplifier 866 senses the voltage level at the sensing data line “SDL” 868 and causes SAout 882-1 to go high when the voltage level at SDL 868 exceeds the reference voltage Vref fed to the reference signal input 870. In one embodiment, the amplifier 866 has the data latch function and latches the state of SAout 882-1 as shown in FIG. 23B.

The operations of the Discharge 920, “B/L Precharge 922, Cell Data Development 924 and Data Sense 926 take “core read time”, which is, for example, approximately 60 ns.

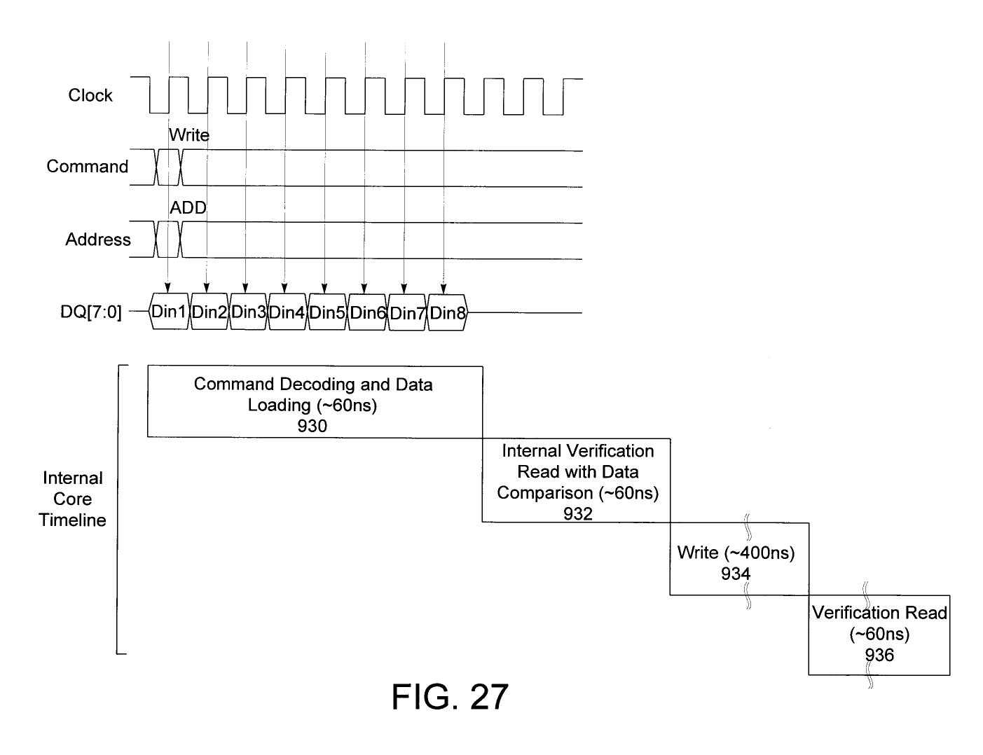

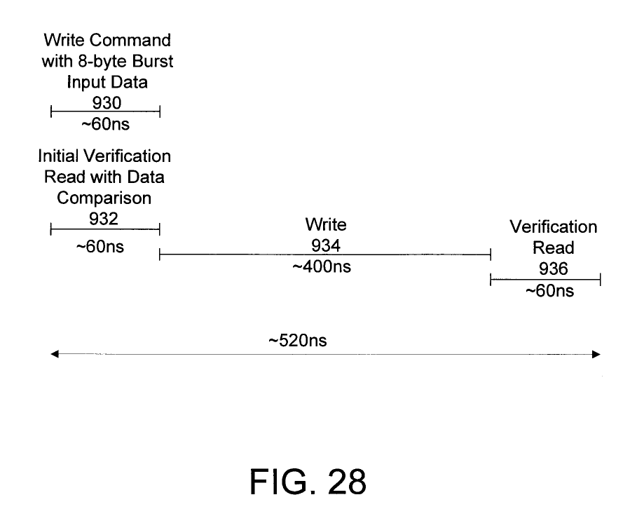

FIGS. 26 and 27 show the timing relationship for the various steps of verifying a successful WRITE operation to obtain the resistance distribution shown in FIG. 13. Referring to FIG. 26 and with reference to FIGS. 14 and 18, a WRITE command results in eight bytes of input data being loaded in register 530 at step 930 (e.g., steps 421-423 in FIG. 14). In an example, step 930 takes approximately 60 ns to perform eight cycles with a 133 MHz clock. At step 932, the initial verification read with data comparison is performed in approximately 60 ns, substantially the same as the duration of step 930. The verification read stores the result of the read in the write driver and sense amplifier 526-1 (e.g., step 424 in FIG. 14).

The data comparison (e.g., steps 425-426 in FIG. 14) occurs in the write driver and sense amplifier 526-1 with exclusive NOR gates for example. In another example, the data comparison occurs in the register 530 (e.g., a content addressable memory (CAM)). If the initial verification read and data comparison indicates a failed previous write operation (e.g., step 426) and the maximum number of writes have not reached (e.g., step 427), then the memory is written at step 934. In one embodiment, step 934 takes approximately 400 ns. Step 936 performs a subsequent verification read for write verification in approximately 60 ns. The total duration of steps 930-936 ns is approximately 580 ns.

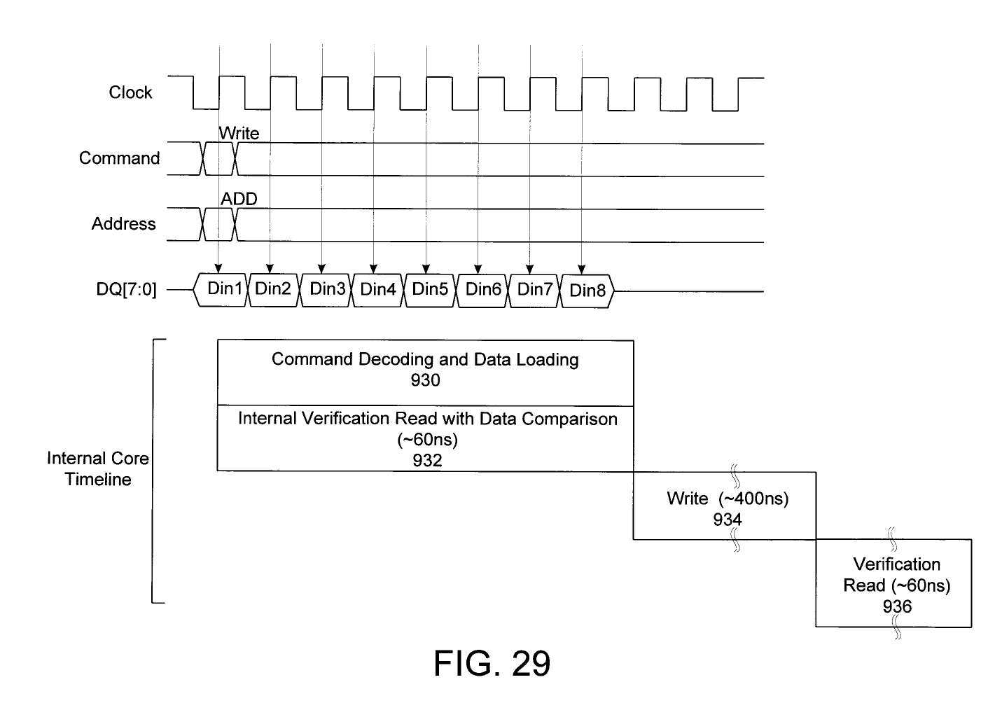

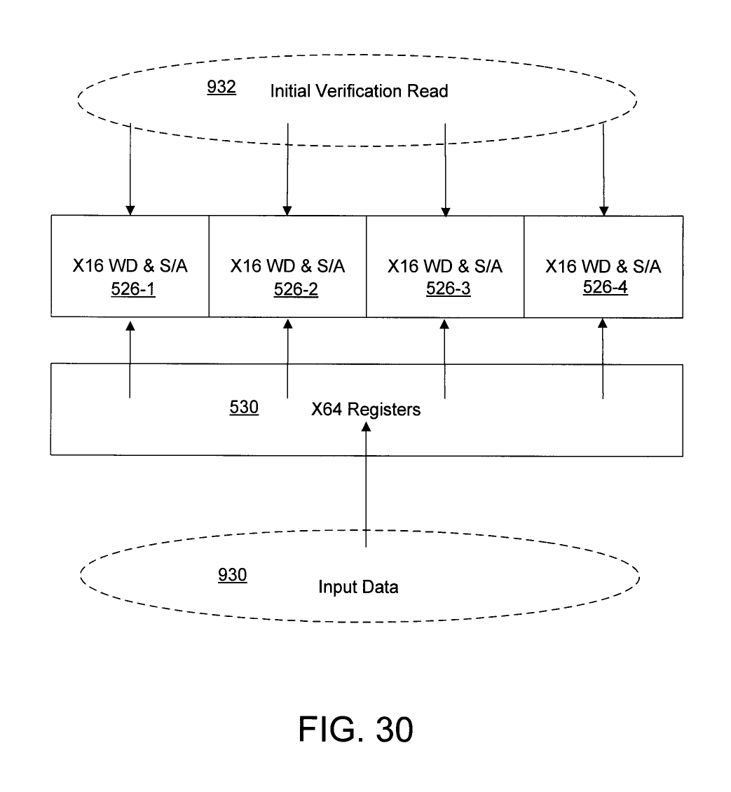

FIG. 28 is a timing diagram illustrating an example verification of a write operation according to an embodiment of the present invention. FIG. 29 is a timing diagram illustrating the write operation showing SDR burst timing according to an embodiment of the present invention. The timing relationship shown in FIGS. 28 and 29 depict the various steps of verifying a successful WRITE operation to obtain the resistance distribution shown in FIG. 13. In the embodiment of the present invention, the initial verification read (e.g., step 930) is performed substantially contemporaneous with step 932, with a total duration of steps 930-936 approximately equal to 520 ns.

Referring to the figures, a WRITE command results in eight bytes of input data being loaded in register 530 at step 930 (e.g., steps 421-423 in FIG. 14). In an example, step 930 takes approximately 60 ns to perform eight cycles with a 133 MHz clock. At step 932, the initial verification read with data comparison is performed in parallel with the duration of step 930. The verification read stores the result of the read in the write driver and sense amplifier 526-1 (e.g., step 424 in FIG. 14). Such storing operation is performed by the amplifier 866 having the data latch function as shown in FIG. 23B. The latch circuit 894 stores the verification read data provided from the amplifier/comparator circuit 892 in response to the control input 896. The latched data is provided for the purpose of comparison.

The data comparison (e.g., steps 425-426 in FIG. 14) occurs in the write driver and sense amplifiers 526-1-526-4 with exclusive NOR gates for example. In another example, the data comparison occurs in the register 530. If the initial verification read and data comparison indicates a failed previous write operation (e.g., step 426) and the maximum number of writes have not reached (e.g., step 427), then the memory is written at step 934. In one embodiment, step 934 takes approximately 400 ns (see the core write time in FIG. 25A). Step 936 performs a subsequent verification read for write verification in approximately 60 ns (see the core read time of FIG. 25B). The total duration of steps 930, 932-936 ns is approximately 520 ns.

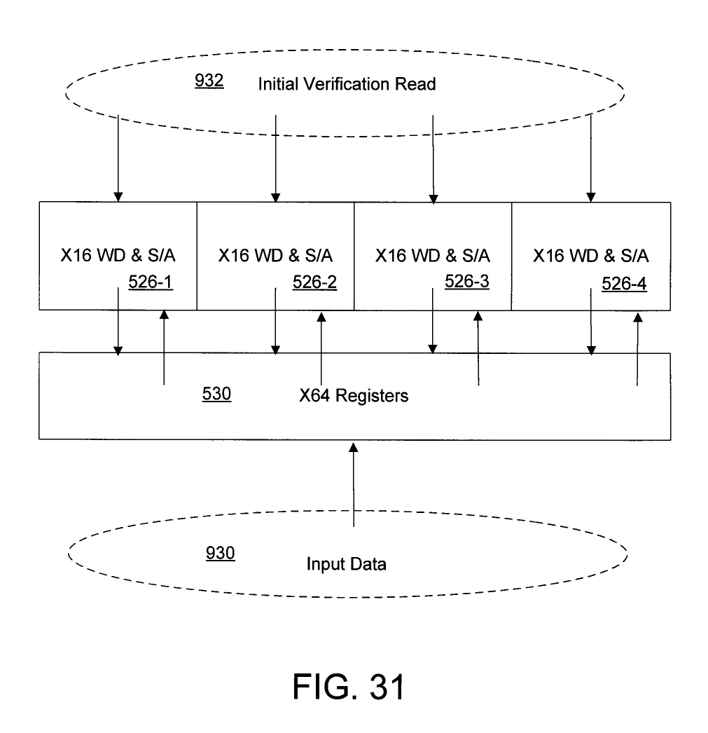

FIG. 30 shows the flow of data for performing the equivalence function in one of the write driver and sense amplifiers (e.g., the first write driver and sense amplifier 526-1). The input data “Data_930”” is held in the register 530 and the verification read data is held in the write driver and sense amplifier 526-1. In one embodiment, the sense amplifier output 882-1 (FIG. 23) and the input data Data_930 stored in the register 530 are in communication, either directly or indirectly, with an exclusive NOR gate. The output of the exclusive NOR gate communicates with the write driver (FIG. 22), either directly or indirectly, as the Data_mask signal 790. In an example, the data comparison is performed in the write driver and sense amplifiers 526-1-526-4.

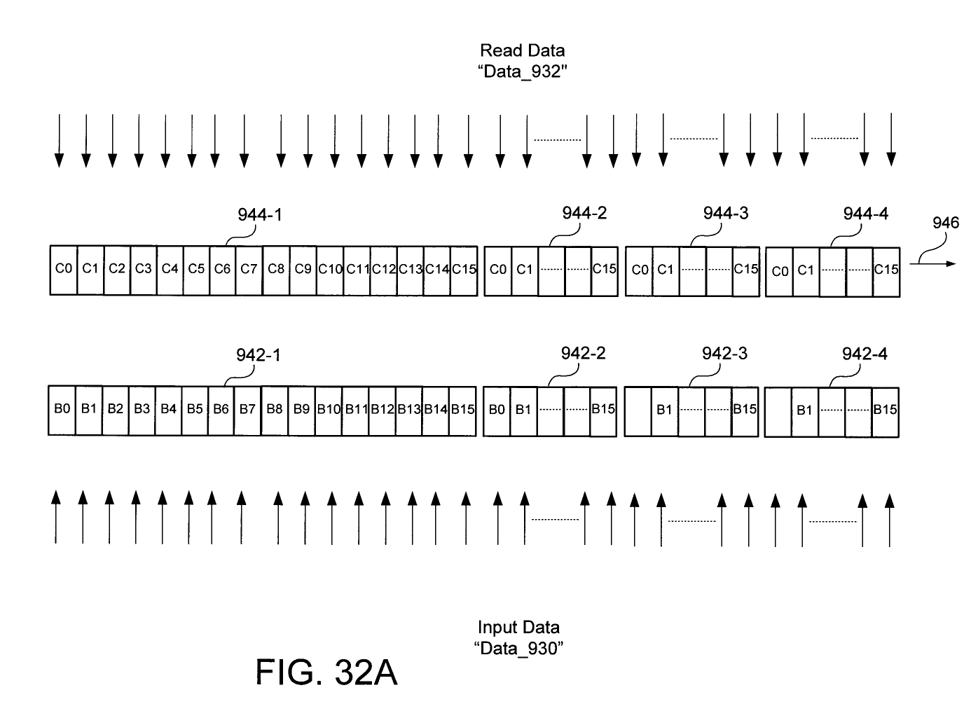

FIG. 31 shows the flow of data for performing the equivalence function in the register 530 shown in FIG. 18. The input data Data_930 is held in the register 530 and the verification read is held in the write driver and sense amplifier 526-1. A register stores the input data and has a memory port that connects to the verification read data provided by the sense amplifier output 882-1 (FIG. 23). The register communicates a signal to the write driver (FIG. 22) indicating whether the input data Data_930 and the sense amplifier output 882-1 match or not.

When the data from the verification read “Data_932” matches the input data for write Data_930, the Data_mask 790 (FIG. 22) is “1”, thereby disabling NOR gates 794 and 796 (FIG. 22). The write driver output 756-1 drives no current (e.g., tri-state or “X”). When the data from the verification read Data_932 does not match the input data for write Data_930, the Data_mask 790 is “0”, thereby enabling NOR gates 794 and 796 (FIG. 22). The write driver output 756-1 drives a current determined by the state of the input data for write Data_930 (e.g., a RESET current 778 or a SET current 780). In an example, the data comparison is performed in the register 530.

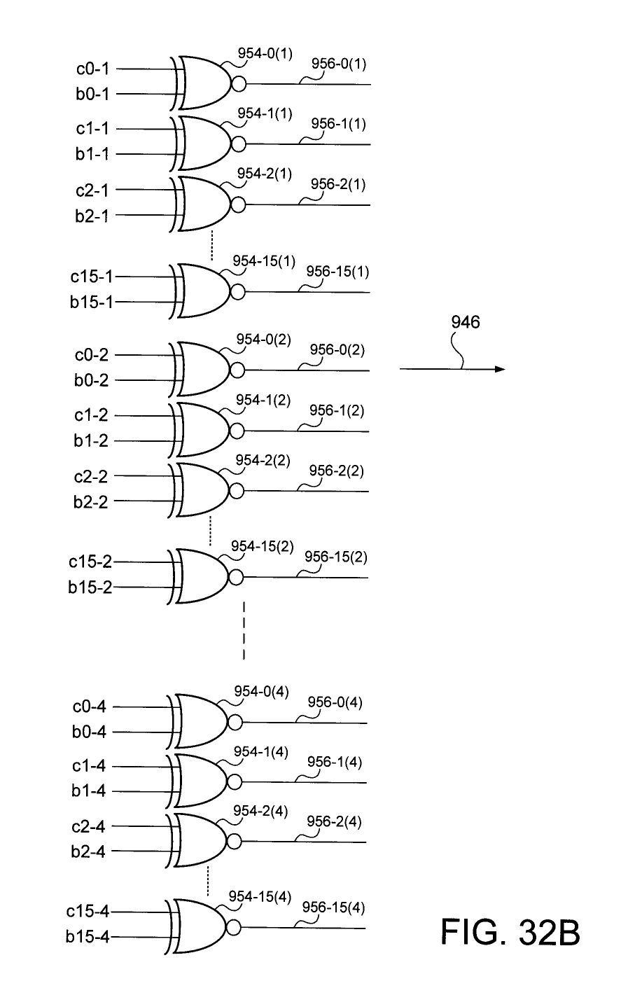

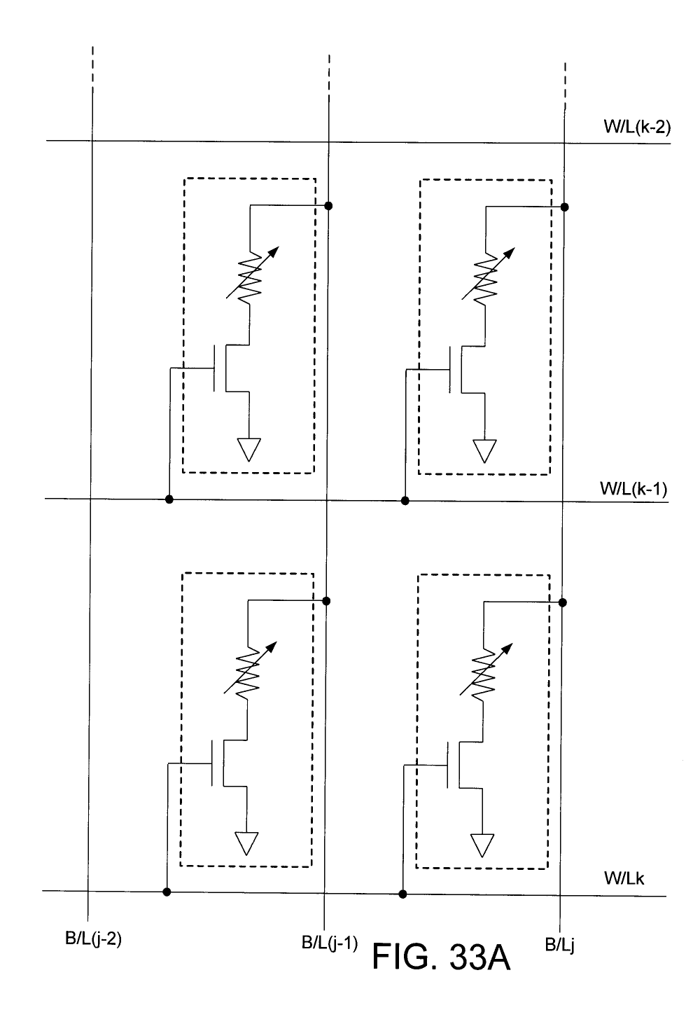

FIG. 32A shows the register 530 shown in FIGS. 18, 31 and 31. Referring to the figures, the register 530 has four 16-bit registers 942-1-942-4. The register 530 receives the input data for write Data_930. First two bits, which correspond to two bits for I/O 0 & 1 (PCM cell sub-array 1 542-1), through the two-bit data path 532-1 and are stored in bits B0, B2 and B1, B3 of the first 16-bit register 942-1. First two bits, which correspond to two bits for I/O 2 & 3 (PCM cell sub-array 1 542-2), are provided through the two-bit data path 532-2 and are stored in bits B0, B2 and B1, B3 of the second 16-bit register 942-2. First two bits, which correspond to two bits for I/O 4 & 5 (PCM cell sub-array 1 542-3), provided through the two-bit data path 532-3 and are stored in bits B0, B2 and B1, B3 of the third 16-bit register 942-3. First two bits, which correspond to two bits for I/O 6 & 7 (PCM cell sub-array 1 542-4), provided through the two-bit data path 532-4 and are stored in bits B0, B2 and B1, B3 of the fourth 16-bit register 942-4.

Similarly, second two bits, which correspond to every two bits for I/Os 0 & 1, 2 & 3, 4 & 5, and 6 & 7, provided through two-bit data paths 532-1-532-4 and stored in bits B4, B6 and B5, B7 of the 16-bit registers 942-1-942-4. Furthermore, two bits corresponding to I/Os are stored in the remaining bits of the 16-bit registers 942-1-942-4.

In an example, four 16-bit comparators 944-1-944-4 are included in the register 530. In another example, four 16-bit comparators 944-1-944-4 are included in the write driver and sense amplifiers 526-1-526-4.

For example, the comparators are formed by exclusive NOR gates and bit-by-bit comparison is performed. The received eight-bit data of the data from the verification read Data_932 is compared to the stored input data for write Data_930. The comparator outputs a comparison result 946.

FIG. 32B shows an example of the 16-bit comparators 944-1-944-4. The comparators comprise 16 exclusive NOR gates 954-0(1)-954-15(1), 954-0(2)-954-15(2), 954-0(3)-954-15(3), and 954-0(4)-954-15(4). Each of the exclusive NOR gates has first and second inputs. The first inputs of the four groups of 16 exclusive NOR gates receive the respective bit data of the input data “Data_930” (b0-1-b15-1, b0-2-b15-2, b0-3-b15-3, b0-4-b15-4). The second inputs of the four groups of 16 exclusive NOR gates receive the respective bit data of the read data “Data_932” (c0-1-c15-1, c0-2-c15-2, c0-3-c15-3, c0-4-c15-4).

The 16 exclusive NOR gates 954-0(1)-954-15(1), 954-0(2)-954-15(2), 954-0(3)-954-15(3), and 954-0(4)-954-15(4) compare the bit data of the read data “Data_932” (c0-1-c15-1, c0-2-c15-2, c0-3-c15-3, c0-4-c15-4) to the respective input data “Data_930” ((b0-1-b15-1, b0-2-b15-2, b0-3-b15-3, b0-4-b15-4), and provide comparison outputs 956-0(1)-956-15(1), 956-0(2)-956-15(2), 956-0(3)-956-15(3), and 956-0(4)-956-15(4), respectively, as the comparison result 946.

In the example of the WRITE, the data input for the initial verification at step 930 is performed by storing the input data by the eight-bit register 942. The initial verification read with data comparison at step 932 is performed by comparing the stored data bits B1-B8 to the eight-bit read data SAout 1-SAout 8. In the operations of two steps 930 and 932 are, however, performed in parallel. The eight-bit read data SAout 1-SAout 8 is kept (or latched) in the sense amplifier circuits of the write driver and sense amplifiers, the sense amplifier circuits having the data latch function (see FIG. 23B). The comparison results from the comparator are provided to the write driver circuitry of the write driver and sense amplifiers. The write drive circuitry performs the write operation as described above (see FIG. 25A). Thereafter, the subsequent verification read for write verification is performed at step 936, the operation of which is similar to that of step 932.

Examples of the data from the verification read Data_932 and the input data for write Data_930 and their comparison results are shown in Table 3. For simplicity, the data is shown as eight bits.

TABLE 3
Data and Comparison

| Data_in | Di1 | Di2 | Di3 | Di4 | Di5 | Di6 | Di7 | Di8 |
|---|---|---|---|---|---|---|---|---|
| Read Data | 1 | 0 | 0 | 1 | 0 | 1 | 0 | 1 |
| “Data_932” | | | | | | | | |
| Input Data | 1 | 1 | 0 | 0 | 1 | 1 | 1 | 1 |
| “Data_930” | | | | | | | | |
| Data Match? | Y | N | Y | N | N | Y | N | Y |
| Data to | X | 1 | X | 0 | 1 | X | 1 | X |
| be Written | | | | | | | | |
| Data_Mask | 1 | 0 | 1 | 0 | 0 | 1 | 0 | 1 |
| Signal 790 | | | | | | | | |

The data from the verification read Data_932 is compared to the input data for write Data_930. In the particular example, data corresponding to Di1, Di3, Di6 and Di8 matches each other and the data does not require to be rewritten (shown by “X”). Data corresponding to Di2, Di 4, Di5 and Di7 does not, however, match each other and the data needs to be rewritten. The data to be rewritten (Di2, Di 4, Di5 and Di7) is “1”, “0”, “1”, “1” and it is provided to the corresponding data line driving circuits 770-2, . . . , as Data in 2_2, . . . as shown in FIG. 22. At the same time, Data_mask “1” signal 790 is fed to the first data line driving circuit 770-1 and the third, sixth and eighth data line driving circuits and thus, the NOR gates 794 and 796 of these data line driving circuits are disabled. Data_mask “0” signal 790 is fed to the second data line driving circuit 770-2 and the fourth, fifth and seventh data line driving circuits and thus, the NOR gates 794 and 796 of these data line driving circuits are enabled. It is assumed that the WDEb is controlled to “low”. Data “1”, “0”, “1”, “1” is as input data to the NOR gate 794 of the second data line driving circuit 770-2 and the fourth, fifth and seventh data line driving circuits. In response to the “0” input data, the current “I_{R}” 778 flows in the fourth data line driving circuit. In response to the “1” input data, the current “I_{S}” 780 flows in the second data line driving circuit 770-2 and the fifth and seventh data line driving circuits. Mirror currents of the currents “I_{R}” and “I_{S}” flow through the corresponding write data line (WDL) and further flows through the global bitlines selected by the write global column selection signals GYW1-GYW16, the local bitlines selected by the local column selection signals Y1, Y2, , . . . , Ym and the wordlines selected by the pre-row-decoder outputs “Xq”, “Xr” and “Xs”. The programmable volume 130 of GST 126 of the PCM cells connected to the selected bitlines and wordlines develop the “reset” and “set” states in response to the currents I_Reset and I_Set as shown in FIGS. 4B and 3.

In another example, the four 16-bit comparators 944-1-944-4 are located between the register 530 and the write driver and sense amplifiers 526-1-526-4.

In another example, the latch 894 of FIG. 23B is unnecessary when the sensed output is compared to the input data directly by a comparison circuit. Also, the sensed output may be directly fed to the logic circuitry for controlling data writing in the data driver as shown in FIG. 22.

In the above mentioned memory cells of the embodiments and examples, implemented are diode based PCM cells as shown in FIG. 6. Diodes are two-terminal switching elements. The PMC cells of the FET based PCM cell shown in FIG. 7 and the bipolar transistor based PCM cells shown in FIG. 8 can be implemented. Such implementations as FET and bipolar based PCM cells need replace the vertical P-N diode as the anode 186 and the cathode 188 shown in FIG. 10 to form the emitter, base of a bipolar transistor and the drain, gate of a P-channel FET, the collector of the bipolar transistor and the source of the FET being grounded. Because bipolar transistors and FETs are three-terminal switching elements, circuit structures of controlling bipolar and FET based PCM cells may be different from those of the diode based PCM cells.

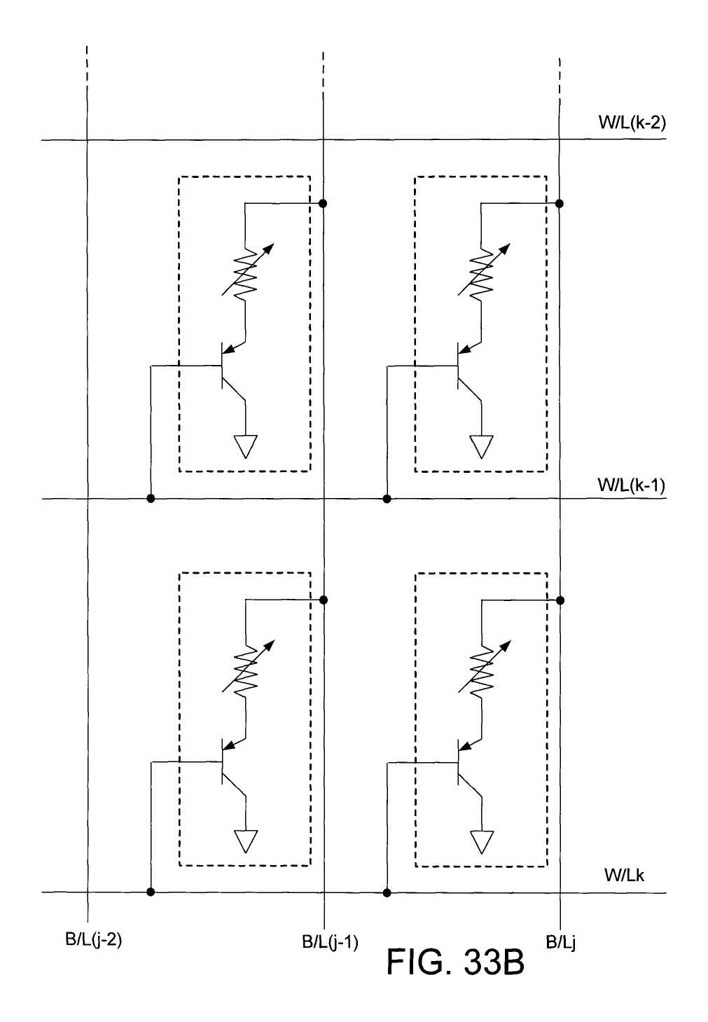

FIGS. 33A and 33B show other examples of PCM cell arrays applicable to memory devices according to embodiments of the present invention. A memory cell array shown in FIG. 33A includes a plurality of PCM cells including FETs as switching elements. A memory cell array shown in FIG. 33B includes a plurality of PCM cells including bipolar transistors as switching elements.

According to the embodiments of the present invention, there is provided a phase change memory device with feature of iterative verification of programmed data.

In the embodiments, specific circuits, devices and elements are used as examples. Various alterations can be implemented. For example, the polarity of devices and voltage may be changed and bipolar transistors and FETs having opposite polarity may be used.

In the embodiments described above, the device elements and circuits are connected to each other as shown in the figures, for the sake of simplicity. In practical applications of the present invention, elements, circuits, etc. may be connected directly to each other. As well, elements, circuits etc. may be connected indirectly to each other through other elements, circuits, etc., necessary for operation of devices and apparatus. Thus, in actual configuration, the circuit elements and circuits are directly or indirectly coupled with or connected to each other.

The above-described embodiments of the present invention are intended to be examples only. Alterations, modifications and variations may be effected to the particular embodiments by those of skill in the art without departing from the scope of the invention, which is defined solely by the claims appended hereto.

1.-59. (canceled)

60. A method for writing data into a phase change memory having a plurality of memory cells, comprising:
receiving input data comprising a plurality of bits;
reading previous data comprising a plurality of bits read from the plurality of memory cells;
comparing the input data with the previous data in parallel with the reading;
determining whether one or more of bits are different between the input data and the previous data to provide a data determination result; and;
programming the one or more of the plurality of memory cells with the input data in response to the data determination result.

61. The method of claim 60, further comprising determining whether a count value is less than a maximum value to provide a count determination result.

62. The method of claim 61, wherein the programming is performed and updating the count value in response to the data determination result and count determination result.

63. The method of claim 60, wherein the receiving input data further comprises receiving a burst of the input data, the burst including a plurality of data.

64. The method of claim 63, wherein the receiving a burst of the input data comprises:
receiving the burst of the input data with a single data rate (SDR), wherein each of the plurality of data is clocked on one clock edge, or
receiving the burst of the input data with a double data rate (DDR), wherein each of the plurality of data is clocked on one of a rising and a falling clock edge.

65. The method of claim 60, further comprising:
storing the input data in a register; and
storing the previous data in a comparator having a data store function,
the comparing the input data with the previous data comprising comparing the stored input data with the stored previous data occurring in the comparator with the comparison results communicated to a write driver, or comparing the stored input data with the stored previous data occurring in
the register with the comparison results communicated to a write driver.

66. The method of claim 60, wherein
the count value is initially set to an initial value and is updatable.

67. The method of claim 60, further comprising indicating a fail when the count value reaches a predetermined value.

68. An apparatus for writing data into a phase change memory, comprising:
a sense amplifier configured to sense a memory state being a set state or reset state of a plurality of memory cells;
a retainer configured to retain the state of a plurality of bits in data;
a write driver having a write current branch, a reset current branch and a set current branch,
the reset current branch enabled by a RESET state and disabled by a data-mask state,
the set current branch being enabled by a SET state and disabled by the data-mask state,
the write current branch being mirroring a current of one of the reset current branch and the set current branch; and
an equivalence circuit configured
to set the data-mask state corresponding to a bit in the data having the SET state when a corresponding sensed bit in the plurality of memory cells has the SET state, and
to set the data-mask state corresponding to a bit in the data having the RESET state when a corresponding sensed bit in the plurality of memory cells has the RESET state.

69. The apparatus of claim 68, wherein the sense amplifier comprises a bias transistor and a differential voltage amplifier, the bias transistor being in communication with a positive input of a differential voltage amplifier,
one of a plurality of memory cells being in communication with the positive input of the differential voltage amplifier,
a sense voltage at the positive input of the differential voltage amplifier being in proportion to a bias resistance of the bias transistor and a memory cell resistance of the one of the plurality of memory cells,
a reference voltage being in communication with a negative input of the differential voltage amplifier, the reference voltage being between the sense voltage obtained at the positive input of the differential voltage amplifier for the one of the plurality of memory cells in the SET state and the one of the plurality of memory cells in the RESET state.

70. The apparatus of claim 68, wherein the equivalence circuit comprises logic circuitry, the logic circuitry comprising an exclusive-NOR circuit, the corresponding sensed bit in communication with one input of the exclusive-NOR circuit, and the bit in the data in communication with another input of the exclusive-NOR circuit, wherein the equivalence circuit comprises a retainer for retaining a state, wherein the plurality of memory cells includes a phase change memory.

71. The apparatus of claim 70, wherein a first duration for the register to receive a burst of data substantially overlaps with a second duration for the sense amplifier to sense one of the plurality of memory cells and for the equivalence circuit to set the data-mask state, the burst of the data including data defined by a predetermined number of data units.

72. A phase change memory system comprising:
a memory array including a plurality of memory cells, each of the plurality of memory cells located at one of a plurality of rows and at one of a plurality of columns;
a plurality of local column selectors, each local column selector being in communication with a plurality of columns;
a global column selector in communication with the plurality of local column selectors;
a sense amplifier configured to sense a memory state being a set state or reset state of a plurality of memory cells;
a register configured to retain the state of a plurality of bits in data;
a write driver in communication with the global column selector, the write driver having a write current branch, a reset current branch and a set current branch,
the reset current branch enabled by a reset state and disabled by a data-mask state,
the set current branch enabled by a set state and disabled by the data-mask state,
the write current branch mirroring a current of one of the reset current branch and the set current branch; and
an equivalence circuit configured
to set the data-mask state corresponding to a bit in the data having the set state when a corresponding sensed bit in the plurality of memory cells has the set state, and
to set the data-mask state corresponding to a bit in the data having the reset state when a corresponding sensed bit in the plurality of memory cells has the reset state.

73. The phase change memory system of claim 72, wherein the sense amplifier is in communication with the global column selector, the sense amplifier including a bias transistor and a differential voltage amplifier,
the bias transistor in communication with a positive input of a differential voltage amplifier,
one of a plurality of memory cells in communication with the positive input of the differential voltage amplifier,
a sense voltage at the positive input of the differential voltage amplifier being in proportion to a bias resistance of the bias transistor and a memory cell resistance of the one of the plurality of memory cells,
a reference voltage in communication with a negative input of the differential voltage amplifier, the reference voltage being between the sense voltage obtained at the positive input of the differential voltage amplifier for the one of the plurality of memory cells in the set state and the one of the plurality of memory cells in the reset state.

74. The system of claim 73, wherein the equivalence circuit comprises logic circuitry.

75. The system of claim 74, wherein the logic circuitry comprises an exclusive-NOR circuit, the corresponding sensed bit in communication with one input of the exclusive-NOR circuit, and the bit in the data in communication with another input of the exclusive-NOR circuit, wherein the equivalence circuit comprises a retainer for retaining a state, wherein the plurality of memory cells includes a phase change memory, wherein a first duration for the register to receive a burst of data substantially overlaps with a second duration for the sense amplifier to sense one of the plurality of memory cells and for the equivalence circuit to set the data-mask state, the burst of the data including a predetermined number of units of data.

76. The system of claim 75, wherein the predetermined number of units of data comprises a predetermined number of bytes or bits of data, the data being formed by a data word, the retainer performing the function of holding a data state in response to a control signal, the retainer further performing the function of comparing data states.

77. A phase change memory (PCM) comprising:
an array having a plurality of memory cells with k rows×j columns, each of k and j being an integer greater than one;
a column selector configured to select at least one of the j columns;
a row selector configured to select at least one of the k rows;
a data writer configured to provide input data to selected one or ones of the plurality of memory cells through the selected one or ones of the columns and rows;
an input data retainer configured to retain the input data; and
a data write controller configured to control the data writer,
the data writer comprising
a first current circuit configured to perform a first current flow when a first state of the input data,
a second current circuit configured to perform a second current flow when a second state of the input data, and
a third current circuit configured to perform a third current flow, the third current being proportional to the first current and the second current in the first and second states of the input data, and
operations of the first and second current circuits being controlled by the data write controller.

78. The PCM of claim 77, wherein the column selector comprising a local column selector and a global column selector,
the local column selector being configured to select one or more columns from m groups of the j columns, j/m being global columns, m being an integer,
the global column selector being configured to select one or more global columns,
the PCM further comprising a data reader configured to read data written in one or ones of the plurality of memory cells through the selected one or ones of the columns and rows.

79. The PCM of claim 78, wherein:
the first state of the input data corresponds to a reset state, the first current flowing through the first current circuit in response to the reset state;
the second state of the input data correspond to a set state, the second current flowing through the second current circuit in response to the set state; and
the third current is a mirror current of the first or second current.

80. The PCM of claim 79, wherein the data reader is configured to provide a range for reading each of reset and set data, the data write controller enabling or disabling the first and second current circuits in response to control signal, the PCM further comprising a data comparator configured to compare the read data and the input data, wherein the comparator provides a determination signal in comparison of the read data to the input data, the determination signal indicating a difference between the two data,
wherein the determination signal indicates when bit states of the read data and input data are different, the comparator is located in the data writer, in the data reader or between the data reader and the data writer, the data write controller is responsive to the determination signal to write the data bit of the input data, the data bit corresponding to the bit determined as different from the read data.

81. The PCM of claim 80, further comprising a determiner configured to determine a write failure in response to the determination signal, wherein:
in a case where no write failure is provided, the data writer is enabled to write the bit different of the input data different from that of the read data in response to the indication of the data difference; and
in a case where a write failure is provided, no further data write is performed in response to the control signal by the data write controller.

82. The PCM of claim 77, wherein the comparator comprises logic circuitry configured to compare data bits of the read data and the input data, the logic circuitry comprising NOR gates or exclusive NOR gates, the PCM further comprising a read data retainer configured to retain the read data, the retained read data being compared to the retained input data, the read data retainer is located in the data reader, in the data writer or between the data reader and the data writer.

83. The PCM of claim 82, wherein the j/m (=u) global columns are t grouped, t being an integer.

84. The PCM of claim 83, wherein j, k, m and t are 1024, 512, eight and 16, respectively.

85. The PCM of claim 82, wherein:
the data writer includes t data line drivers connected to t write data lines, the mirror current flowing in each of the write data lines; and
the data reader includes t sense amplifiers connected to t read data lines, a bias data read current flowing in each of the read data lines, wherein:
the u/t (=w) global columns correspond to one write data line and one read data line.

86. The PCM of claim 85, wherein:
the w global columns are connected to one common write data line through write path control circuitry; and
the w global columns are connected to one common read data line through read path control circuitry.

87. The PCM of claim 85, wherein:
the write path control circuitry includes w transmission gates; and
the read path control circuitry includes w transistor circuits.

88. The PCM of claim 85, wherein the w transmission gates and the w transistor circuits are controlled by a plurality of global column select signals.

89. The PCM of claim 85, wherein the local column selector includes a plurality of local column select transistors controlled by a plurality of a local column select signals.

90. The PCM of claim 88, wherein
each of the plurality of memory cells comprises a two-terminal device or a three-terminal device;
the two-terminal device comprises a diode based memory cell;
the three-terminal device comprises a bipolar transistor or a field effect transistor based memory cell.

91. A memory system comprising a plurality of memory banks, each bank comprising a plurality of phase change memory (PCM) cell arrays, each array comprising PCM defined by claim 18.

92. The memory system of claim 91, further composing bank multiplexer and demultiplexer and input and output circuitry,
the bank multiplexer and demultiplexer being configured to communicate with the plurality of banks to send and receive main data;
the input and output circuitry being configured to communicate with the bank multiplexer and demultiplexer to send and receive the main data.

93. The memory system of claim 91, wherein each of the plurality of memory banks comprises four PCM cell arrays.
